(19) United States
(12) Patent Application Publication
(10) Pub. No.: US 2023/0402385 A1
(43) Pub. Date: Dec. 14, 2023

(54) GRAPHENE-CLAD METAL INTERCONNECT

(71) Applicant: Taiwan Semiconductor Manufacturing Co., Ltd., Hsinchu (TW)

(72) Inventors: Jian-Hong LIN, Huwei (TW); Yinlung LU, Hsinchu (TW); Jun HE, Hsinchu (TW); An Shun TENG, Hsinchu (TW); Chun-Wei CHANG, Taoyuan (TW)

(73) Assignee: Taiwan Semiconductor Manufacturing Co., Ltd., Hsinchu (TW)

(21) Appl. No.: 17/837,664

(22) Filed: Jun. 10, 2022

(51) Int. Cl. H01L 23/532; H01L 21/8234; H01L 27/088; H01L 23/528; H01L 21/768; H01L 23/522

(52) U.S. Cl. CPC H01L 23/53295; H01L 21/823475; H01L 27/088; H01L 23/5283; H01L 23/53238; H01L 23/53266; H01L 21/76843; H01L 21/76816; H01L 21/76807; H01L 23/5226; H01L 23/53276

(57) ABSTRACT

A graphene-clad metal interconnect extends material properties of graphene to both damascene and patterned interconnect structures at lower metal layers, leading to significant reductions in resistance. Graphene cladding can be used with or without a metal barrier/liner. Presence of a barrier/liner can serve to catalyze growth of an overlying graphene layer. Graphene may also be selectively grown on barrier surfaces. Fully integrated structures and process flows for integrated circuits with graphene-clad metallization are described.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (FinFETs). Metal lines connecting the transistors can also be scaled down accordingly. Such scaling down has increased the complexity of semiconductor manufacturing processes.

### BRIEF DESCRIPTION OF THE DRAWINGS

Aspects of the present disclosure are best understood from the following detailed description when read with the accompanying figures. It is noted that, in accordance with common practice in the industry, various features are not drawn to scale. In fact, the dimensions of the various features may be arbitrarily increased or reduced for clarity of discussion.

FIG. 1 is a cross-sectional view of a pair of transistors coupled to a graphene-clad interconnect structure, in accordance with some embodiments.

FIG. 2 is a flow diagram of a method for fabricating the interconnect structure shown in FIG. 1, in accordance with some embodiments.

FIG. 3 is a cross-sectional view of a graphene-clad damascene interconnect structure, in accordance with some embodiments.

FIG. 4 is a flow diagram of a method for fabricating the graphene-clad damascene interconnect structure shown in FIG. 3, in accordance with some embodiments.

FIGS. 5A-5E are cross-sectional views of the graphene-clad damascene interconnect structure shown in FIG. 3 at various stages of its fabrication process, in accordance with some embodiments.

FIG. 6 is a cross-sectional view of a graphene-clad damascene interconnect structure, in accordance with some embodiments.

FIG. 7 is a flow diagram of a method for fabricating the graphene-clad damascene interconnect structure shown in FIG. 6, in accordance with some embodiments.

FIGS. 8A-8E are cross-sectional views of the graphene-clad damascene interconnect structure shown in FIG. 6 at various stages of its fabrication process, in accordance with some embodiments.

FIG. 9 is a cross-sectional view of a graphene-clad damascene interconnect structure, in accordance with some embodiments.

FIG. 10 is a flow diagram of a method for fabricating the graphene-clad damascene interconnect structure shown in FIG. 9, in accordance with some embodiments.

FIGS. 11A-11E are cross-sectional views of the graphene-clad damascene interconnect structure shown in FIG. 9 at various stages of its fabrication process, in accordance with some embodiments.

FIG. 12 is a cross-sectional view of a graphene-clad patterned interconnect structure, in accordance with some embodiments.

FIG. 13 is a flow diagram of a method for fabricating the graphene-clad patterned interconnect structure shown in FIG. 12, in accordance with some embodiments.

FIGS. 14A-14D are cross-sectional views of the graphene-clad patterned interconnect structure shown in FIG. 12 at various stages of its fabrication process, in accordance with some embodiments.

FIG. 15 is a cross-sectional view of a graphene-clad patterned interconnect structure in which the via includes carbon nanotubes, in accordance with some embodiments.

FIG. 16 is a flow diagram of a method for fabricating the graphene-clad patterned interconnect structure shown in FIG. 15, in accordance with some embodiments.

FIGS. 17A-17E, 18, and 19A-19C are cross-sectional views of the graphene-clad patterned interconnect structure shown in FIG. 15 at various stages of its fabrication process, in accordance with some embodiments.

### DETAILED DESCRIPTION

The following disclosure provides different embodiments, or examples, for implementing different features of the provided subject matter. Specific examples of components and arrangements are described below to simplify the present disclosure. These are, of course, merely examples and are not intended to be limiting. For example, the formation of a first feature on a second feature in the description that follows may include embodiments in which the first and second features are formed in direct contact, and may also include embodiments in which additional features may be formed that are between the first and second features, such that the first and second features are not in direct contact.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “nominal” as used herein refers to a desired, or target, value of a characteristic or parameter for a component or a process operation, set during the design phase of a product or a process, together with a range of values above and/or below the desired value. The range of values can be due to slight variations in manufacturing processes or tolerances.

In some embodiments, the terms “about” and “substantially” can indicate a value of a given quantity that varies within 20% of the value (e.g., ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

The term “vertical,” as used herein, means nominally perpendicular to the surface of a substrate.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

Graphene is a molecular form of carbon graphite in which carbon atoms are arranged in a planar, or two-dimensional, hexagonal lattice. Graphene has unique material properties, including superior electrical and thermal conductivity, as well as favorable mechanical properties. The structure of graphene provides a long mean free path for movement of electric charge and allows for conduction of high current densities. Graphene has one of the highest electron mobilities among the materials used in the electronics industry—significantly higher (e.g., about 100 times higher) than the electron mobility of silicon. The electrical resistivity of graphene is significantly lower (e.g., about one-third lower) than that of copper. Graphene films that are one atomic layer thick can have very high tensile strength while remaining transparent.

Because of its properties, graphene is suitable for use in interconnect design. In addition to reducing resistivity and increasing thermal conductivity of interconnects, graphene may be used as a diffusion barrier to control electromigration and time-dependent dielectric breakdown (TDDB), which have been longstanding failure mechanisms in interconnect designs. Diffusion barriers may be desirable for copper interconnects for additional reasons. For example, a diffusion barrier can be used to prevent copper from reacting with neighboring insulators, such as silicon oxides (e.g., SiO₂), which could cause the copper to oxidize. Such a diffusion barrier can also prevent copper from reacting with polyimide, causing corrosion and associated material defects. Use of a graphene diffusion barrier thus can improve reliability of interconnects.

Copper interconnects have been widely used in the production of advanced integrated circuits. Copper interconnects can be formed using a damascene process. In the damascene process, a pattern of trenches is formed in an insulating material, and then the trenches are filled with copper using a plating process, e.g., electroplating or electro-less plating in a liquid plating solution. The damascene process does not require patterning and etching copper. In a dual damascene process, trenches for vias and metal lines can be formed and filled together as a single structure.

Depositing graphene films with sufficient adhesion to copper interconnects can be challenging. High temperatures in a range from about 500° C. to about 1000° C. may be required when using a chemical vapor deposition (CVD) process. Growing sufficiently thick graphene layers on copper to achieve desired conductivity improvements can also be challenging because the growth rate of graphene is highly dependent on the carbon solubility of the substrate metal.

One way to leverage the advantages of graphene is to cap damascene metal layers with one or more monolayers of graphene. Copper metal lines capped with graphene can experience a reduction in resistance of more than about 50% by modifying interfacial electron scattering characteristics. Copper metal lines capped with less than about 1 nm of graphene can take ten times longer to fail than metal lines that are capped with about 2 nm of cobalt tungsten phosphide (CoWP). In addition, capacitance can improve by more than a factor of three for a single atomic layer of graphene on copper metal lines, compared with an about 2-nm thick TaN barrier layer.

Another way to leverage the advantages of graphene is to enclose multiple sides of one or more metal lines with graphene. The resulting graphene-clad metal interconnect can extend the benefit of a graphene cap to the interconnect structure. Graphene cladding may be more advantageous at lower metal layers, e.g., M₁ to M₅, where a smaller pitch can lead to increased reduction in resistance. The graphene cladding may be used with or without a metal barrier/liner. Presence of a barrier/liner can serve to catalyze growth of the overlying graphene layer. Graphene may also be selectively grown on barrier surfaces. In some instances it may be advantageous to use a barrier-free design, for example, to improve electrical contact between vias and underlying metal.

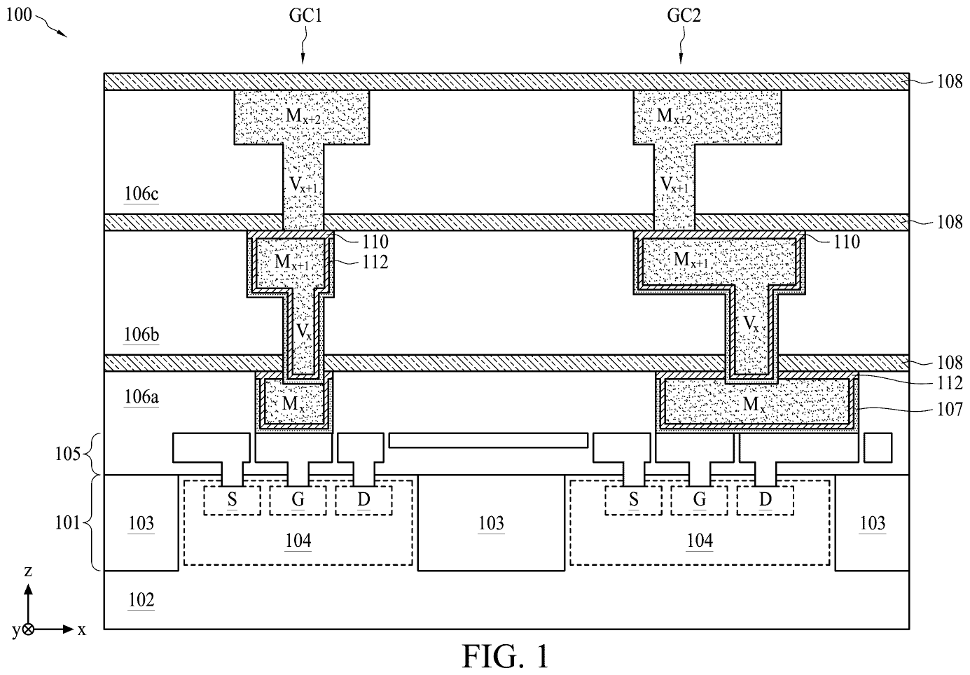

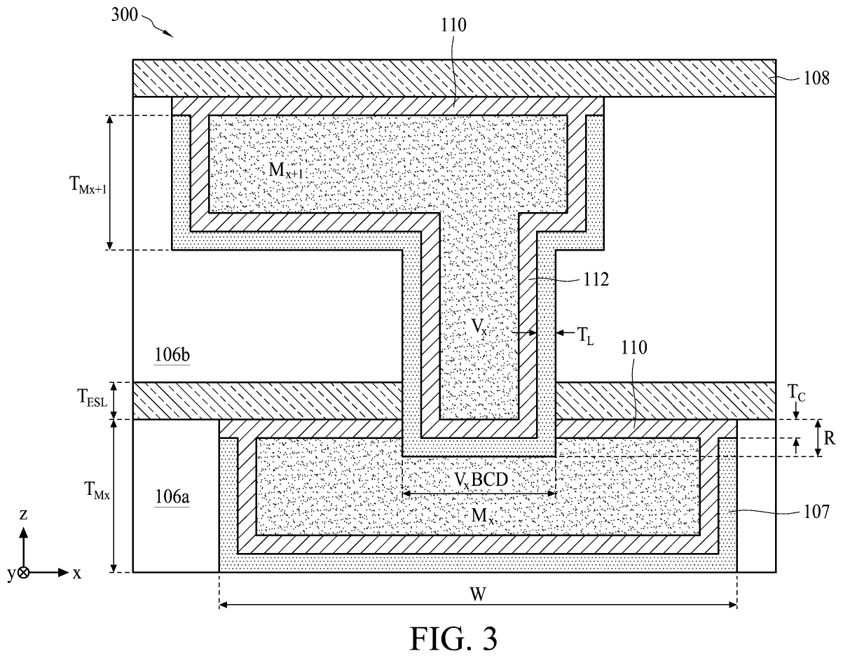

FIG. 1 shows a cross-sectional view of an integrated circuit 100 incorporating graphene-clad metal interconnect structures, e.g., GC1 and GC2, according to some embodiments. Integrated circuit 100 includes a transistor layer 101, a substrate 102, a contact layer 105, and inter-layer dielectric (ILD) layers 106a and 106b. Graphene-clad metal interconnect structures GC1 and GC2 are fabricated above transistor layer 101 and provide connections between contacts to terminals of transistors 104 throughout integrated circuit 100. For example, GC1 may be coupled to the gate terminal of a transistor, while GC2 connects gate and drain terminals of another transistor, as shown in FIG. 1. Various embodiments of GC1 and GC2 are presented herein in FIGS. 3, 6, 9, 12, and 15, with descriptions of methods for their formation. In each of these embodiments, graphene-clad metal interconnect structures GC1 and GC2 include a lower metal line “Mₓ,” an upper metal line “Mₓ₊₁,” and a vertical connection (e.g., in the z-direction), or via “Vₓ,” between the upper and lower metal lines—when Mₓ represents, for example, metal 1, and Mₓ₊₁ represents metal 2; when Mₓ represents metal 2, and Mₓ₊₁ represents metal 3, and so on. Liners 107 may be formed on interior surfaces of one or both metal lines as well as on interior surfaces of via Vₓ. ILD layers 106a and 106b provide electrical insulation around the metal lines and vias. Etch stop layers 108 can be used to delineate adjacent ILD layers 106a and 106b and to protect underlying films from damage from deposition of low-k dielectrics, such as SiN, silicon carbon nitride (SiCN), silicon carbide (SiC), aluminum oxide (AlO or Al₂O₃), and aluminum nitride (AlN). In some embodiments, etch stop layers 108 form compressive stress and improve adhesion of adjacent layers. Each graphene-clad metal interconnect structure GC1, GC2 may also include graphene cladding 112 around vias Vₓ.

Integrated circuit 100 may include additional vias and metal lines stacked on top of graphene-clad metal interconnect structures GC1 and GC2. For example, Vₓ₊₁ and Mₓ₊₂ in ILD layer 106c. Additional vias and metal lines may also be graphene-clad interconnect structures, or they may be copper damascene structures or patterned interconnect structures without the addition of graphene (as shown in FIG. 1), or combinations thereof.

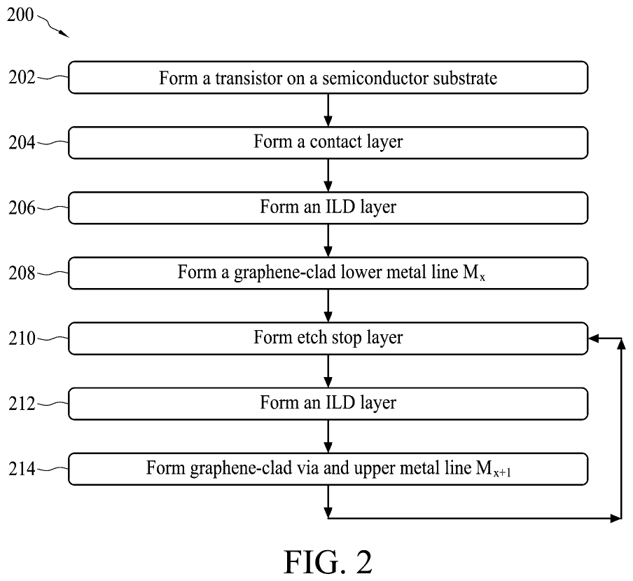

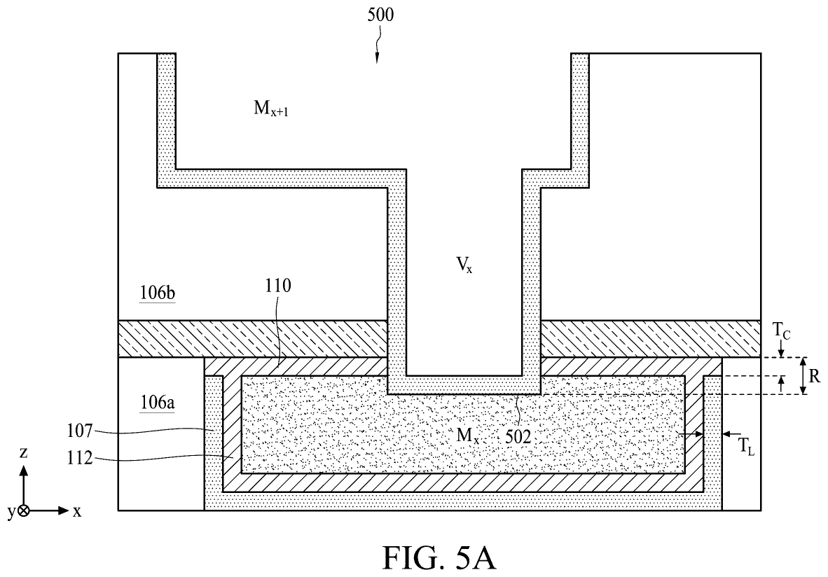

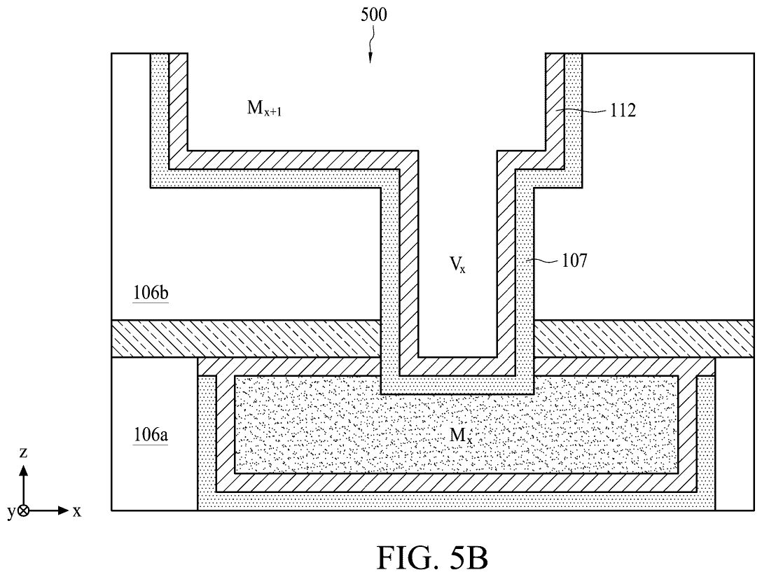

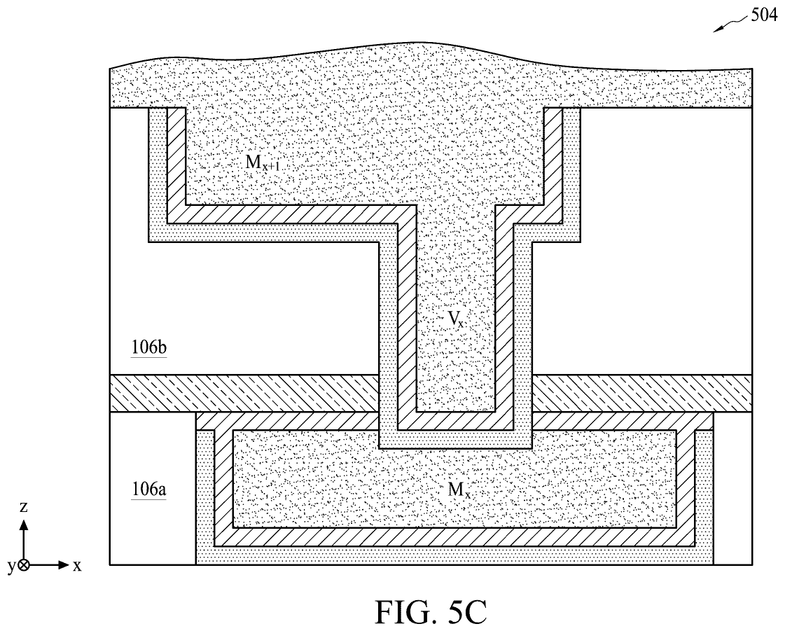

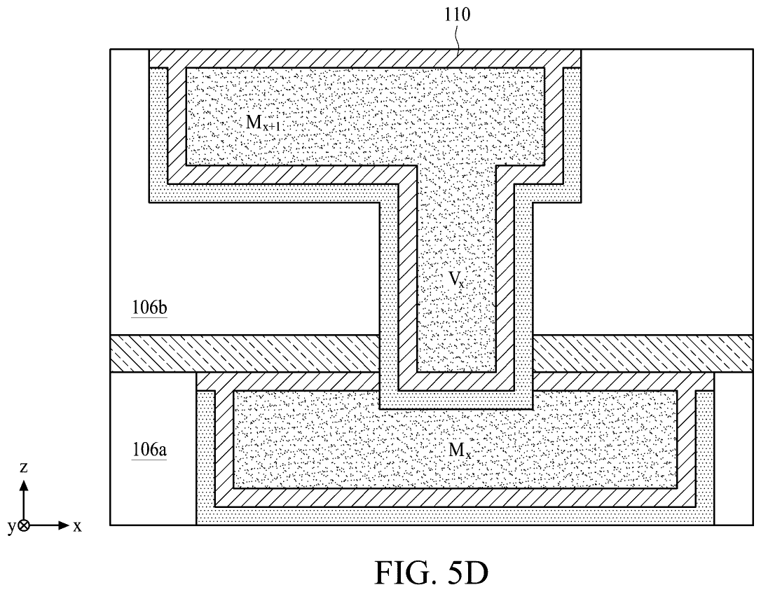

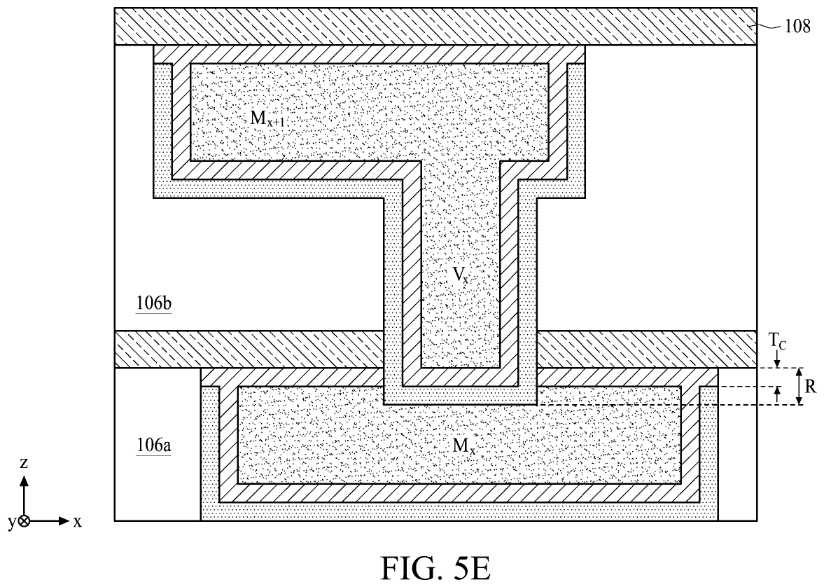

FIG. 2 illustrates a method 200 for fabricating integrated circuit 100 that includes graphene-clad metal interconnect structures GC1 and GC2, according to some embodiments. For illustrative purposes, operations illustrated in FIG. 2 will be described with reference to processes for fabricating graphene-clad metal interconnect structures GC1 and GC2 as illustrated in FIGS. 5A-5E, 8A-8E, and 11A-11E, which are cross-sectional views of graphene-clad metal interconnect structures at various stages of their fabrication, according to some embodiments. Operations of method 200 can be performed in a different order, or not performed, depending on specific applications. It is noted that method 200 may not produce a complete integrated circuit 100. Accordingly, it is understood that additional processes can be provided before, during, or after method 200, and that some of these additional processes may be briefly described herein.

Referring to FIG. 2 in operation 202, transistors 104 are formed on substrate 102 as shown in FIG. 1, in accordance with some embodiments. As used herein, the term “substrate” describes a material onto which subsequent material layers are added. Substrate 102 itself may be patterned. Materials added on substrate 102 may be patterned or may remain unpatterned. Substrate 102 can be a bulk semiconductor wafer or the top semiconductor layer of a semiconductor-on-insulator (SOI) wafer (not shown), such as silicon-on-insulator. In some embodiments, substrate 102 can include a crystalline semiconductor layer with its top surface parallel to (100), (110), (111), or c-(0001) crystal plane. Alternatively, substrate 102 may be made from an electrically non-conductive material, such as a glass, sapphire, or plastic. Substrate 102 can be made of a semiconductor material, such as silicon (Si). In some embodiments, substrate 102 can include (i) an elementary semiconductor, such as germanium (Ge); (ii) a compound semiconductor including silicon carbide (SiC), gallium arsenide (GaAs), gallium phosphide (GaP), indium phosphide (InP), indium arsenide (InAs), and/or indium antimonide (InSb); (iii) an alloy semiconductor including silicon germanium carbide (SiGeC), silicon germanium (SiGe), gallium arsenic phosphide (GaAsP), gallium indium phosphide (InGaP), gallium indium arsenide (InGaAs), gallium indium arsenic phosphide (InGaAsP), aluminum indium arsenide (InAlAs), and/or aluminum gallium arsenide (AlGaAs); or (iv) a combination thereof. Further, substrate 102 can be doped with p-type dopants (e.g., boron (B), indium (In), aluminum (Al), or gallium (Ga)) or n-type dopants, such as phosphorus (P) or arsenic (As)). In some embodiments, different portions of substrate 102 can have opposite type dopants.

Transistor layer 101 includes shallow trench isolation (STI) regions 103 and transistors 104, each formed with a source S, gate G, and drain D, as illustrated schematically in FIG. 1. Transistors 104 are electrically isolated from one another by STI regions 103. In some embodiments, transistors 104 can be, for example, bipolar junction transistors (BJTs), planar metal oxide semiconductor field effect transistors (MOSFETs), three-dimensional MOSFETs, (e.g., FinFETs, nanowire FETs, and gate-all-around FETs (GAAFETs)), or combinations thereof.

STI regions 103 can be formed adjacent to, or between transistors 104. STI regions 103 can be deposited and then etched back to a desired height. Insulating material in STI regions 103 can include, for example, silicon oxide (SiO₂), silicon nitride (SiN), silicon oxynitride (SiON), fluoride-doped silicate glass (FSG), a low-k dielectric material, and/or other suitable insulating material. In some embodiments, the term “low-k” refers to a low dielectric constant. In the field of semiconductor device structures and manufacturing processes, low-k refers to a dielectric constant that is less than the dielectric constant of SiO₂ (e.g., less than 3.9). In some embodiments, STI regions 103 can include a multi-layered structure. In some embodiments, the process of depositing the insulating material can include any deposition method suitable for flowable dielectric materials (e.g., flowable silicon oxide). For example, flowable silicon oxide can be deposited for STI regions 103 using a flowable chemical vapor deposition (FCVD) process. The FCVD process can be followed by a wet anneal process. In some embodiments, the process of depositing the insulating material can include depositing a low-k dielectric material to form a liner. In some embodiments, a liner made of another suitable insulating material can be placed between STI region 103 and adjacent transistors 104. In some embodiments, STI regions 103 may be annealed and polished to be co-planar with a top surface of transistors 104.

Referring to FIG. 2 in operation 204, contact layer 105 is formed above transistor layer 101 as shown in FIG. 1, in accordance with some embodiments. Contact layer 105 provides electrical connections between transistors 104 and graphene-clad metal interconnect structures GC1 and GC2. The process of forming contact layer 105 can include forming metal silicide layers and/or conductive regions (contacts) within contact openings in an ILD material. The contacts provide electrical connections to source, gate, and drain terminals of transistors 104. In some embodiments, the metal used to form metal silicide layers of contact layer 105 can include one or more of tungsten (W), cobalt (Co), titanium (Ti), and nickel (Ni). In some embodiments, contact metal is deposited by atomic layer deposition (ALD), plasma vapor deposition (PVD), plasma enhanced vapor deposition (PECVD), or chemical vapor deposition (CVD) to form diffusion barrier layers (not shown) along surfaces of contact layer 105. The deposition of diffusion barrier layers can be followed by a high temperature rapid thermal annealing (RTP) process to form metal silicide layers.

The process of forming conductive regions of contact layer 105 can include deposition of a conductive material followed by a polishing process to co-planarize top surfaces of the conductive regions with top surfaces of insulating material surrounding contact layer 105. The conductive materials can be one or more of W, Co, Ti, aluminum (Al), copper (Cu), gold (Au), silver (Ag), or another suitable conductive material, a metal alloy, or a stack of various metals or metal alloys that may include layers, such as a titanium nitride (TiN) layer. The conductive materials can be deposited by, for example, CVD, PVD, PECVD, or ALD. The polishing process for co-planarizing the conductive region with the top surface of contact layer 105 can be a chemical-mechanical planarization (CMP) process. In some embodiments, the CMP process can use a silicon or an aluminum abrasive slurry with abrasive concentrations ranging from about 0.1% to about 3%. In some embodiments, the abrasive slurry may have a pH level less than about 7 for W metal, or a pH level greater than about 7 for Co or Cu metals in the conductive regions.

Referring to FIG. 2 in operation 206, ILD layer 106a is formed above contact layer 105 as shown in FIG. 1, in accordance with some embodiments. ILD layer 106a can be about 1050 Å to about 1350 Å of an insulating material, such as silicon dioxide (SiO₂), fluorosilicate glass (FSG), hard breakdown (HBD), a low-k silicon oxycarbide (“low-k” SiOC/LK5/LK6), an extreme low-k dielectric material, (e.g., silicon oxycarbide nitride (“ELK” SiOCN/LK9S)), and combinations thereof. ILD layer 106a can be made of a single insulating material or a layered stack that includes multiple insulating materials. Such materials have dielectric constants, κ, ranging from about 3.9 for to about 2.5 for ELK. Low-k and extreme low-k dielectrics may vary in their respective carbon concentrations such that a higher concentration of carbon in the SiOC material causes the dielectric constant to be lower.

Referring to FIG. 2 in operation 208, lower metal line Mₓ is formed to incorporate liner 107 and graphene cladding 112, as shown in FIG. 1, in accordance with some embodiments. To form lower metal line Mₓ, a trench can be etched in ILD layer 106a to a depth that, when filled with liner 107, graphene cladding 112, and metal, achieves a desired metal line thickness, e.g., 600 Å-1000 Å. Graphene-clad damascene metal lines Mₓ and Mₓ₊₁ may take different forms and use different methods, of fabrication as described in detail below with respect to the embodiments shown in FIGS. 3, 6, 9, 12, and 15.

Referring to FIG. 2, in operation 210, an etch stop layer 108 can be formed on lower metal line Mₓ, as shown in FIG. 1, in accordance with some embodiments. In some embodiments, etch stop layer 108 includes one or more of SiCN, SiC, SiN, AlN, AlO, Al₂O₃, SiO₂, or other materials that tend to be more etch-resistant than low-k ILD materials, such as SiOC. In some embodiments, etch stop layer 108 can be formed with a compressive strain so as to improve adhesion of underlying graphene cap 110 to metal line Mₓ.

Referring to FIG. 2, in operation 212, ILD layer 106b can be formed above lower metal line Mₓ as shown in FIG. 1, in accordance with some embodiments. ILD layer 106b can be formed in a similar manner as ILD layer 106a, as described above with respect to operation 206. For example, ILD layer 106b can be formed as another low-k or ELK dielectric similar to ILD layer 106a, as described above. In some embodiments, ILD layer 106b can be about 100 Å thicker than ILD layer 106a, in a range from about 1150 Å to about 1450 Å.

Referring to FIG. 2, in operation 214, a graphene-clad via and graphene-clad upper metal line Mₓ₊₁ are formed. Incorporating graphene cladding 112 into the interconnect structure serves to enhance material properties of the metal layer with the superior properties of graphene.

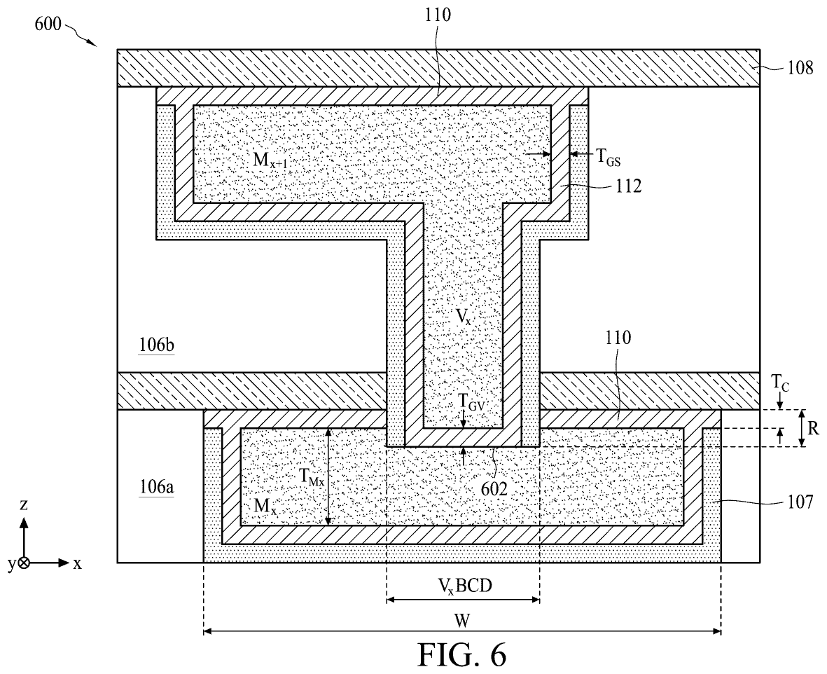

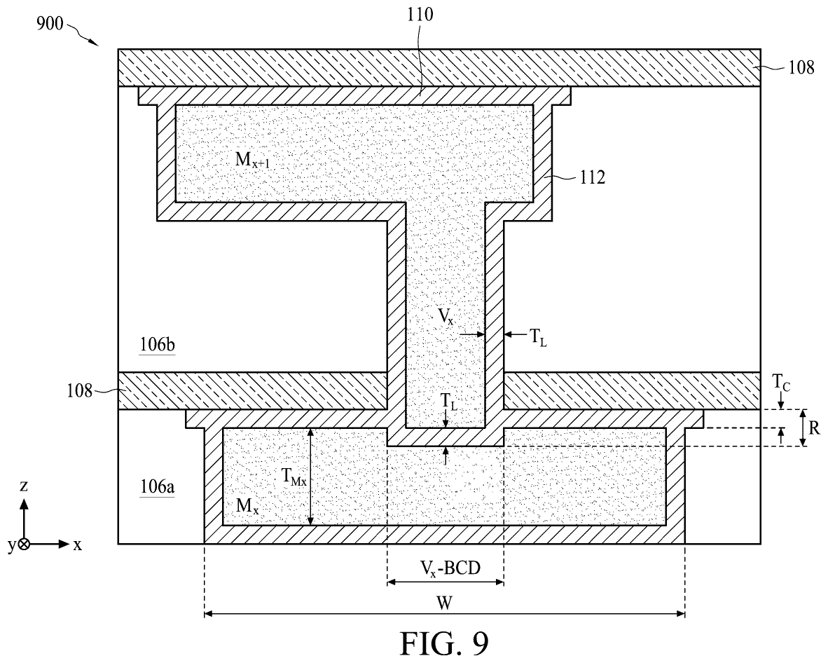

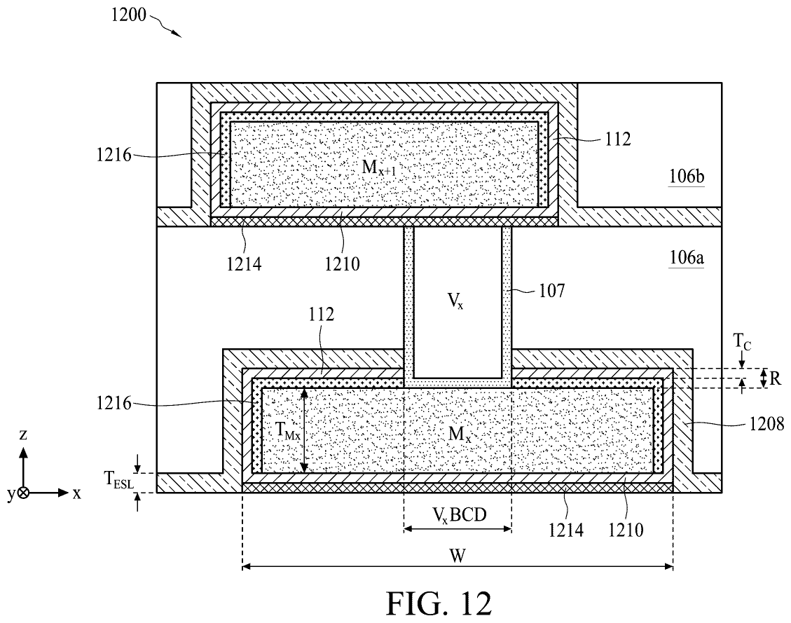

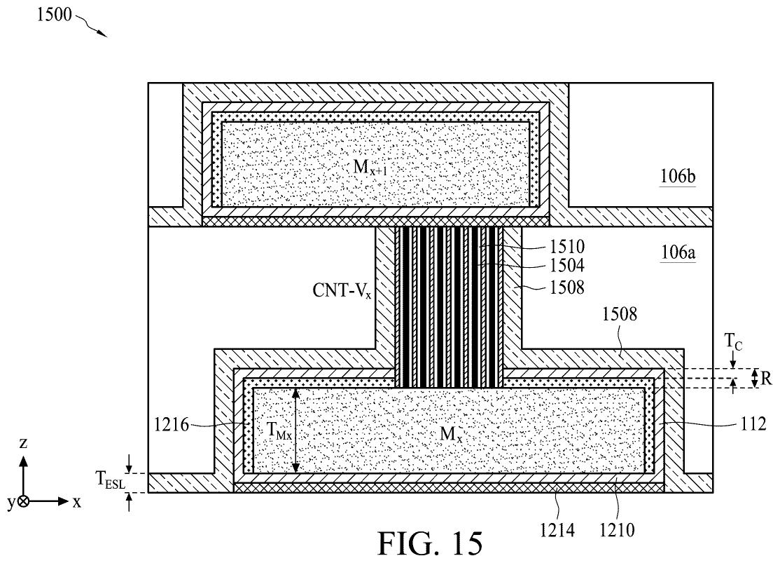

The junction where the bottom of the via Vₓ meets lower metal line Mₓ can have different forms and use different methods of fabrication, as described below with respect to FIGS. 3, 6, 9, 12, and 15. In some embodiments, the junction between Vₓ and Mₓ includes both liner 107 and graphene cladding 112, as shown in FIG. 3. In some embodiments, the junction between Vₓ and Mₓ includes graphene cladding 112 without liner 107, thus forming a barrier-free contact, as shown in FIG. 6. In some embodiments, liner 107 is omitted from the interconnect structure, as shown in FIG. 9. In some embodiments, the junction between Vₓ and Mₓ includes liner 107, but no graphene cladding 112, as shown in FIGS. 12 and 15.

In some embodiments, a via opening and a trench for upper metal line Mₓ₊₁ can be formed together as a dual damascene trench as described in detail below with respect to the embodiments shown in FIGS. 3, 6, and 9. Etching the dual damascene trench can use a process similar to the process for forming contact openings in ILD layer 106a, as described above. The dual damascene trench can then be lined, clad with graphene, and filled with copper. In some embodiments, a single damascene process can be used to form metal lines Mₓ and Mₓ₊₁ and via Vₓ can be etched. In some embodiments, metal lines Mₓ and Mₓ₊₁ and via Vₓ can be formed by lithographic patterning, as described in detail below with respect to the embodiments shown in FIGS. 12, and 15.

Operations 210-214 can then be repeated to form additional vias and metal lines above Mₓ₊₁. In some embodiments, graphene-clad damascene interconnect structures, as described below with reference to FIGS. 3, 6, 9, 12, and 15 may be advantageous for use at layers having smaller pitch, e.g., at an interconnect minimum pitch layer or at a secondary minimum pitch layer, such as at metal layers 1-5.

FIG. 3 shows a cross-sectional view of a graphene-clad damascene interconnect structure 300, e.g., a multi-layer type of graphene-clad metal interconnect structure that could be used as GC1 or GC2 shown in FIG. 1, in accordance with some embodiments. Graphene-clad damascene interconnect structure 300 includes a multi-layer lower metal line Mₓ, a multi-layer upper metal line Mₓ₊₁, and a via Vₓ coupling the multi-layer upper and lower metal lines. Graphene-clad damascene interconnect structure 300 features graphene cladding 112 around a perimeter of lower metal line Mₓ and around a perimeter of the dual damascene structure that includes upper metal line Mₓ₊₁ and via Vₓ. Graphene cladding 112 includes a graphene cap 110 on top surfaces of lower metal line Mₓ and upper metal line Mₓ₊₁. In some embodiments, graphene cap 110 has a thickness, T_{C}, based on a thickness of upper metal line Mₓ₊₁. For example, T_{C} can be less than about T_{Mx+1}/10. Graphene cladding 112 can be a multi-layer structure including up to about 20 layers. More than 20 layers of graphene may not result in further improvement in resistance and thermal conductivity and may cause adhesion issues.

In some embodiments, interior surfaces of graphene-clad damascene interconnect structure 300 further include liners 107 on which graphene cladding 112 can be grown. Liners 107 can also have multiple layers with a total thickness T_{L}. Multi-layer lower metal line Mₓ has a minimum width w as shown in FIG. 3, wherein w includes the widths of liners 107 on both sidewalls of lower metal line Mₓ. In some embodiments, graphene cladding 112 and/or liner 107 can extend across a bottom surface of via Vₓ. In some embodiments, via Vₓ can be recessed into lower metal line Mₓ by a via recess depth R to avoid high contact resistance between via Vₓ and lower metal line Mₓ. In some embodiments, the bottom width of via Vₓ, or “bottom critical dimension” (BCD) of via Vₓ includes the widths of graphene cladding 112 and liner 107 on each via sidewall. In some embodiments, graphene caps 110, having a thickness T_{C}, can be deposited onto top surfaces of one or more conductive metal lines.

In some embodiments, graphene-clad damascene interconnect structure 300 further includes etch stop layers 108 on respective top surfaces of the metal lines. Etch stop layers 108 provide for control of the via etching process. In some embodiments, etch stop layer 108 has a thickness, T_{ESL}, based on a thickness of upper metal line Mₓ₊₁. For example, T_{ESL} can be in a range from about T_{Mx+1}/15 to about T_{Mx+1}/4.

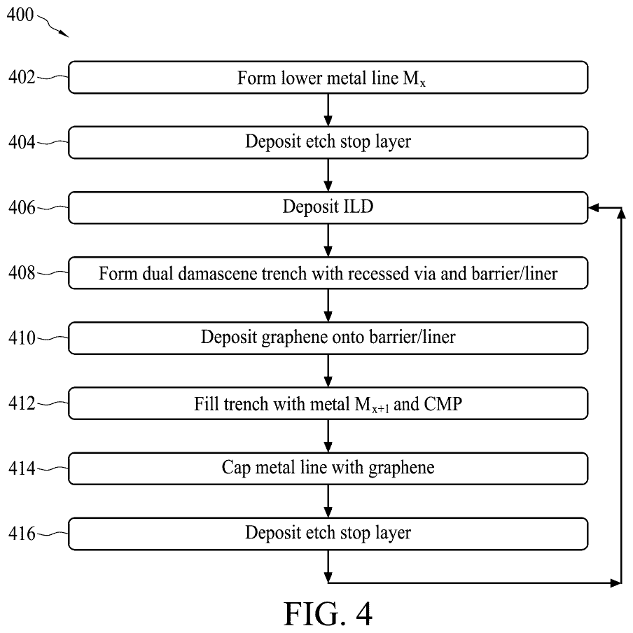

FIG. 4 illustrates a method 400 for fabricating graphene-clad damascene interconnect structure 300, according to some embodiments. Operations illustrated in FIG. 4 will be described with reference to processes for fabricating graphene-clad damascene interconnect structure 300 as illustrated in FIGS. 5A-5E, a sequence of cross-sectional views of graphene-clad damascene interconnect structure 300 at various stages of its fabrication. Operations of method 400 can be performed in a different order, or not performed, depending on specific applications. It is noted that method 400 may not produce a complete graphene-clad damascene interconnect structure 300. Accordingly, it is understood that additional processes can be provided before, during, or after method 400, and that some of these additional processes may be briefly described herein.

Referring to FIG. 4, in operation 402, lower metal line Mₓ is formed as shown in FIG. 5A, in accordance with some embodiments. First, in operation 402, a damascene trench for Mₓ can be etched into ILD layer 106a to a depth that, when filled with metal, achieves a desired metal thickness, e.g., 600 Å-1000 Å. The trench etch process may use, for example, a fluorine-based plasma.

The subsequent metal fill process may incorporate a liner 107 that is deposited on the bottom and sidewalls of the damascene trench prior to plating the bulk metal. Liner 107 can have multiple layers including a thin layer that acts as a diffusion barrier to prevent conductive metal out-diffusion from metal lines Mₓ and Mₓ₊₁ into the adjacent ILD. Liner 107 can also enhance properties of the conductive metal filling of metal line Mₓ. In such embodiments, liner 107 may be referred to as a “barrier+liner” layer. In some embodiments, liner 107, or a top layer of liner 107, can be made of a material that assists in catalyzing growth of graphene, for example, cobalt (Co), tantalum (Ta), ruthenium (Ru), Ti, TiN, cobalt nitride (CoN), or tantalum nitride (TaN), and alloys or combinations thereof. Liner 107, or a lower layer of liner 107, can incorporate an aluminum-copper alloy (AlCu), W, Ti, TiN, Au, Ag, other metal alloys, a metal nitride material, or another suitable metal, or a ceramic material.

The metal fill process may further incorporate formation of graphene cladding 112 over liner 107, prior to plating the bulk metal. Graphene cladding 112 can be selectively deposited onto liner 107 using a CVD, PVD, PE-CVD, or ALD process. Graphene cladding 112 can be made up of up to about 20 graphene atomic mono-layers, such that graphene cladding 112 has a total thickness in a range from about ⅔ wₘᵢₙ to about wₘₐₓ/30, wherein wₘᵢₙ is a minimum value, and wₘₐₓ is a maximum value, of metal width w for metal line Mₓ.

Following formation of liner 107 and graphene cladding 112, the trench can be filled with a high conductivity metal, such as Cu, Co, or W, by electroplating, electro-less plating, a PVD process, or another suitable fill process, to form lower metal line Mₓ. In some embodiments, a copper seed layer can be conformally deposited on graphene cladding 112 using a PVD process, prior to plating bulk copper. In some embodiments, a metal line pattern density characterizing lower metal line Mₓ is in a range from about 19% to about 41%. In some embodiments, a metal line thickness, e.g., T_{M}, is measured from the bottom of liner 107 to the bottom of graphene cap 110, to include both the thickness of liner 107, graphene cladding 112, and the bulk metal thickness of lower metal line Mₓ. When the trench is full, a graphene cap 110 can be formed on the top surface of lower metal line Mₓ as shown in FIG. 5A. In some embodiments, graphene cap 110 has a thickness T_{C} that can be as thick as T_{M}/10.

Referring to FIG. 4, in operation 404, etch stop layer 108 is deposited on metal line Mₓ as shown in FIG. 5A, in accordance with some embodiments. In some embodiments, etch stop layer 108 can be a single blocking layer having a thickness in a range from about 100 Å to about 150 Å. In some embodiments, etch stop layer 108 can be a multi-layer stack that includes, for example, a blocking layer and a TEOS capping layer. Etch stop layer 108 can be formed with a high density and/or a compressive strain so as to improve adhesion of underlying graphene cap 110 to metal line Mₓ. A high compressive strain can be achieved by forming etch stop layer 108 from materials, such as SiN, SiCN, SiC, AlO, Al₂O₃, and AN, using CVD or PVD.

Referring to FIG. 4, in operation 406, ILD layer 106b is deposited, in accordance with some embodiments. ILD layer 106b can be formed similarly as ILD layer 106a described above with reference to FIG. 1.

Referring to FIG. 4, in operation 408, a dual damascene trench 500 is formed in ILD layer 106b and liner 107 is formed on the bottom and sidewalls of the dual damascene trench as shown in FIG. 5B, in accordance with some embodiments. Dual damascene trench 500 includes a vertical portion that will contain via Vₓ and a horizontal portion that will contain upper metal line Mₓ₊₁. The vertical portion of dual damascene trench 500 extends downward through etch stop layer 108 and graphene cap 110 into the bulk metal of lower metal line Mₓ to recess depth R. In some embodiments, recess depth R is about 0.5 to about 5 times the thickness, T_{C}, of graphene cap 110. In some embodiments, the via bottom CD (VₓBCD) is between about 0.5 and about 2 times the minimum metal width, w, of lower metal line Mₓ. Liner 107 is then formed on internal surfaces of dual damascene trench 500, including on a lower trench surface 502 of via Vₓ, using, for example, a conformal deposition process. Liner 107 as applied to dual damascene trench 500 is similar to liner 107 as applied to lower metal line Mₓ in the above description of operation 402.

Referring to FIG. 4, in operation 410, graphene cladding 112 is extended to the bottom and sidewalls of dual damascene trench 500 over liner 107 as shown in FIG. 5B, in accordance with some embodiments. Graphene cladding 112 as applied to dual damascene trench 500 is similar to graphene cladding 112 as applied to inner surfaces of lower metal line Mₓ in the above description of operation 402. Again, graphene cladding 112 can be selectively grown on liner 107 so that the bottom surface of via Vₓ is lined with both liner 107 and graphene cladding 112.

Referring to FIG. 4, in operation 412, upper metal line Mₓ₊₁ is formed as shown in FIG. 5C, in accordance with some embodiments. Via Vₓ and upper metal line Mₓ₊₁ can be filled simultaneously by depositing a highly conductive metal, e.g., Cu, Co, or W, into dual damascene trench 500 using a plating or PVD process, as described above with respect to lower metal line Mₓ. Depositing upper metal line Mₓ₊₁ may over-fill dual damascene trench 500 with copper, creating excess copper 504. Upper metal line Mₓ₊₁ can then be polished as shown in FIG. 5D, in accordance with some embodiments. Polishing can be accomplished using a CMP planarization process, as described above with respect to contact layer 105. Following planarization, excess copper 504 has been removed, and a top surface of upper metal line Mₓ₊₁ is substantially co-planar with top surfaces of liner 107. In some embodiments, a metal line thickness, e.g., T_{Mx+1}, is measured from the bottom of liner 107 to the bottom of graphene cap 110, to include both the thickness of the liner 107, the graphene cladding 112, and the thickness of the bulk metal of the upper metal line Mₓ₊₁. In some embodiments, liners 107 each have a thickness, T_{L}, based on a thickness of upper metal line Mₓ₊₁. For example, T_{L} can be in a range from about T_{Mx+1}/10 to about T_{Mx+1}/4.

Referring to FIG. 4, in operation 414, a graphene cap 110 can be formed on the top surface of upper metal line Mₓ₊₁ as shown in FIG. 5D, in accordance with some embodiments. In some embodiments, graphene cap 110 can be selectively deposited onto the conductive metal surfaces of upper metal line Mₓ₊₁ and liner 107. Graphene cap 110 formed on upper metal line Mₓ₊₁ can be fabricated similarly and can have similar attributes as graphene cap 110 formed on lower metal line Mₓ as described above in operation 402.

Referring to FIG. 4, in operation 416, etch stop layer 108 can be formed on upper metal line Mₓ₊₁ as shown in FIG. 5E, in accordance with some embodiments. Etch stop layer 108 formed on top of upper metal line Mₓ₊₁ can be fabricated similarly and can have similar attributes as etch stop layer 108 formed on top of lower metal line Mₓ as described above in operation 402. Formation of etch stop layer 108 completes graphene-clad damascene interconnect structure 300. Operations 406-416 can then be repeated to form additional dual damascene interconnect structures on top of graphene-clad damascene interconnect structure 300, up to about metal line M5.

FIG. 6 shows a cross-sectional view of a graphene-clad damascene interconnect structure 600, e.g., a graphene-clad metal interconnect structure that could be used as GC1 or GC2 shown in FIG. 1, in accordance with some embodiments. In some embodiments, graphene-clad damascene interconnect structure 600 can be similar to graphene-clad damascene interconnect structure 300, with a few exceptions. Graphene-clad damascene interconnect structure 600 features a barrier-free contact (BFC) 602 at the bottom of via Vₓ. That is, the bottom surface of via Vₓ includes graphene cladding 112 but does not include barrier/liner 107. Therefore, the width of the bottom of via Vₓ, or VₓBCD, includes the thickness of liners 107 on both via sidewalls, but the recess depth R does not. That is, the recess depth R extends downward to the bottom of the graphene cladding at BFC 602. In addition, graphene cladding 112 within graphene-clad damascene interconnect structure 600 may have a non-uniform thickness. In some embodiments, the sidewall thickness T_{GS} of graphene cladding 112 in the dual damascene structure differs from the thickness T_{GV} of graphene cladding 112 on the bottom of Via Vₓ. For example, T_{GS} can be thicker than T_{GV}. Furthermore, the thickness T_{C} of graphene caps 110 can be different from one or both of T_{GS} and T_{GV}. For example, T_{C} can be thicker than T_{GS}, which can be thicker than T_{GV}.

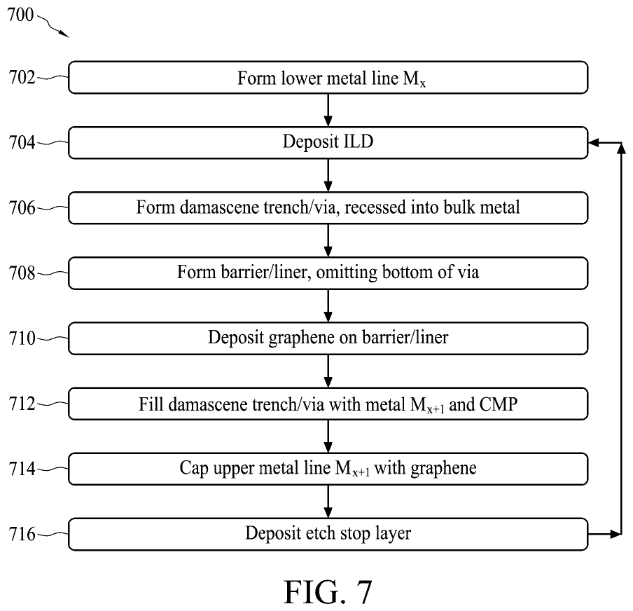

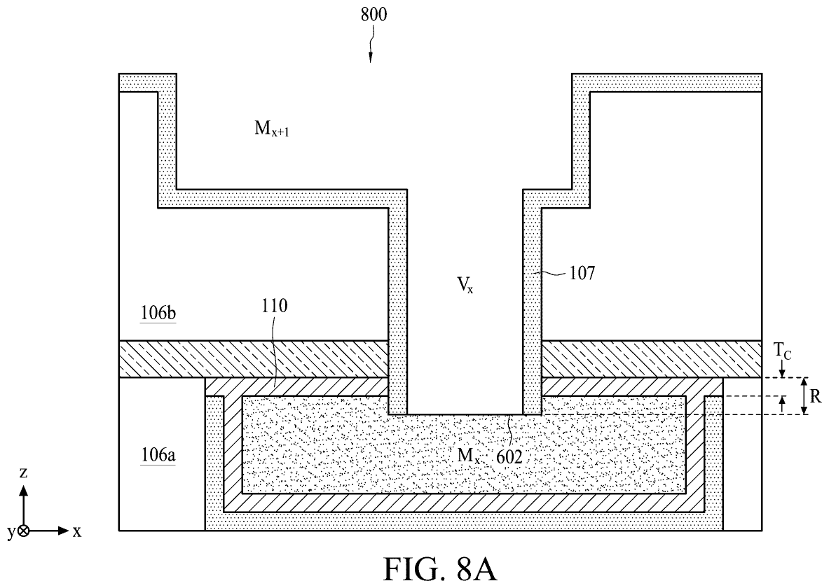

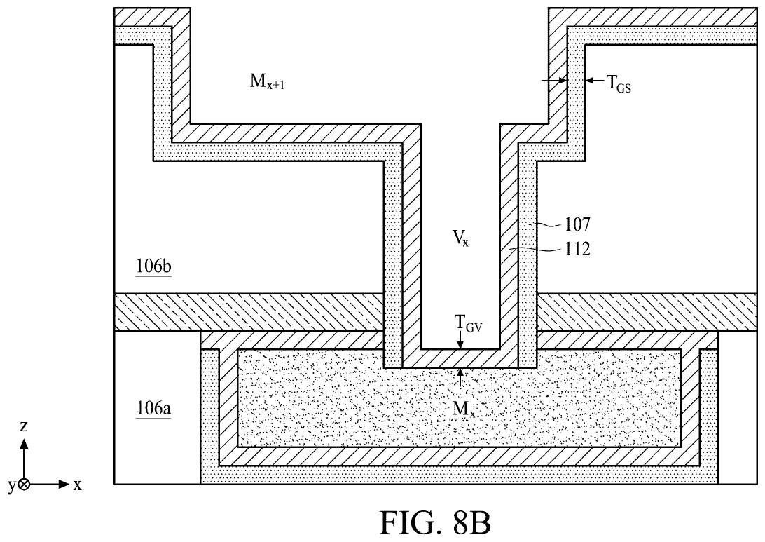

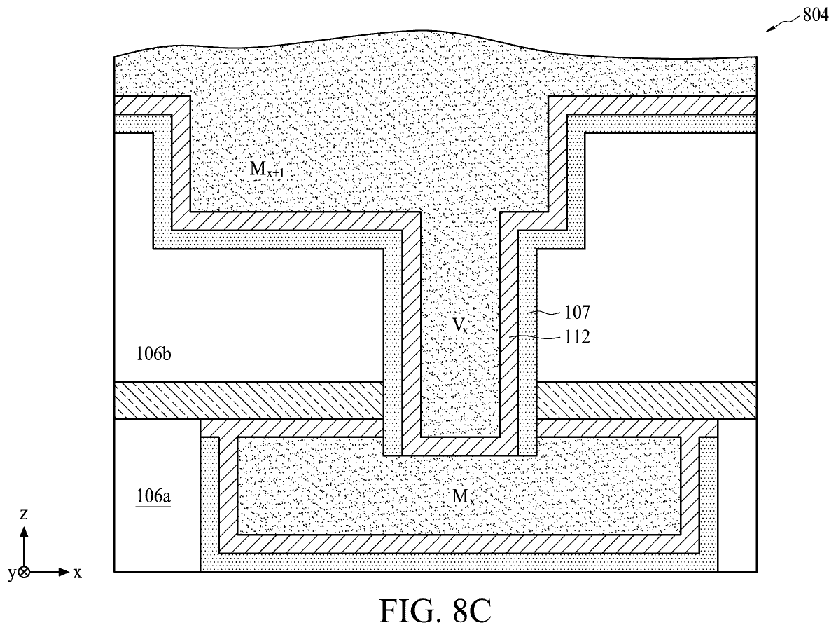

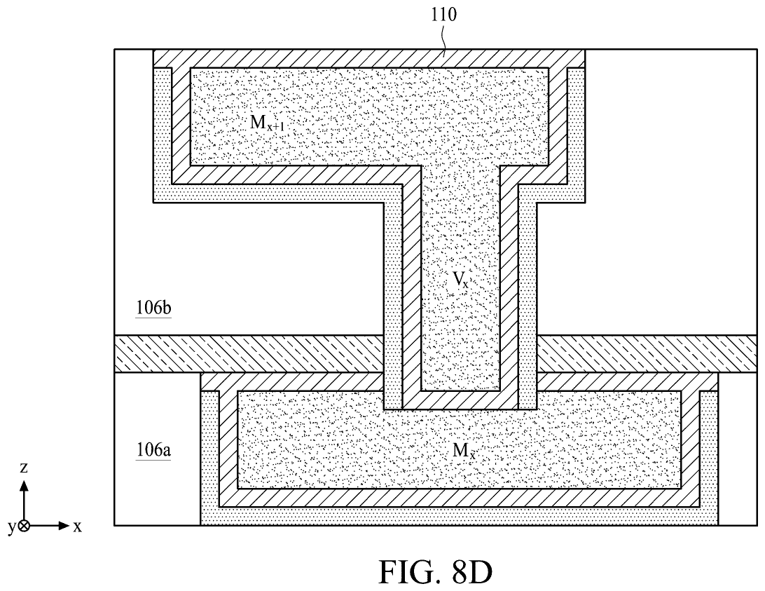

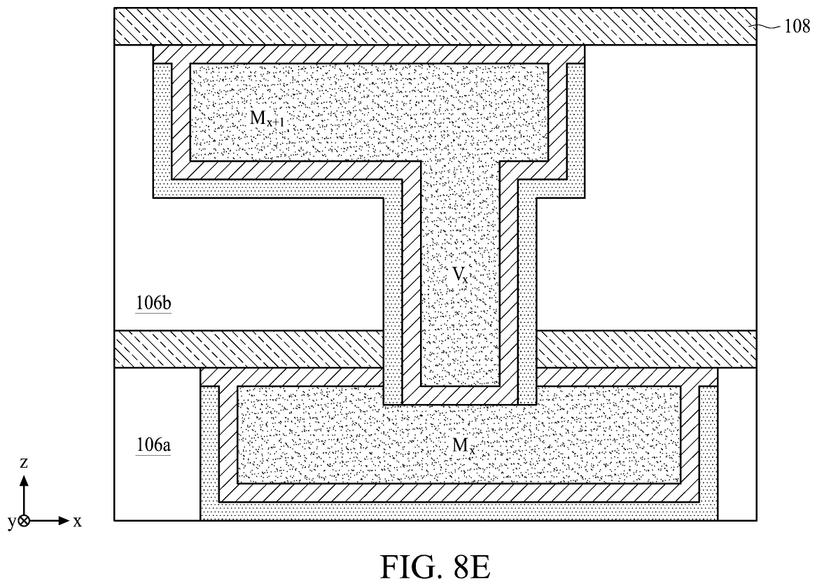

FIG. 7 illustrates a method 700 for fabricating graphene-clad damascene interconnect structure 600, according to some embodiments. Operations illustrated in FIG. 7 will be described with reference to processes for fabricating graphene-clad damascene interconnect structure 600 as illustrated in FIGS. 8A-8E, a sequence of cross-sectional views of graphene-clad damascene interconnect structure 600 at various stages of its fabrication. Operations of method 700 can be performed in a different order, or not performed, depending on specific applications. It is noted that method 700 may not produce a complete graphene-clad damascene interconnect structure 600. Accordingly, it is understood that additional processes can be provided before, during, or after method 700, and that some of these additional processes may be briefly described herein.

Method 700 for fabricating graphene-clad damascene interconnect structure 600 is similar to method 400 for fabricating graphene-clad damascene interconnect structure 300 in many respects, with a few exceptions, in accordance with some embodiments. In some embodiments, operation 706 provides a barrier layer, or liner 107 on internal surfaces of dual damascene trench 500, but not on the bottom of via Vₓ. Alternatively, formation of graphene cladding 112 may be omitted from the bottom of via Vₓ so that the bottom of via Vₓ may have neither liner 107 nor graphene cladding. Different graphene thicknesses can be produced by tuning the selective deposition, which can be accomplished by varying the underlying materials. For example, liner 107 may be made of Co while Mₓ may be made of Cu. Consequently, graphene deposition onto lined sidewalls of via Vₓ may include 3-20 layers of graphene while graphene deposition directly onto metal at the bottom of via Vₓ may include three or fewer layers of graphene.

Referring to FIG. 7, in operation 702, lower metal line Mₓ is formed as shown in FIG. 8A, in accordance with some embodiments. Operation 702 can proceed similarly as in operation 402 as described above, to result in metal line Mₓ shown in FIG. 6, having similar characteristics as a lower metal line Mₓ shown in FIG. 3.

Referring still to FIG. 7, in operation 702, a graphene cap 110 can be formed on lower metal line Mₓ as shown in FIG. 8A, in accordance with some embodiments. When the trench is full, graphene cap 110 can be deposited over the top surface of copper. In some embodiments, graphene cap 110 has a thickness T_{C} that can be as thick as T_{Mx+1}/10. Finally, etch stop layer 108 can be deposited on metal line Mₓ as shown in FIG. 8A, in accordance with some embodiments. In some embodiments, etch stop layer 108 can be formed with a compressive strain so as to improve adhesion of underlying graphene cap 110 to metal line Mₓ. A high compressive strain can be achieved by forming etch stop layer 108 from materials, such as SiN, SiCN, SiC, and AlN. Etch stop layer 108 formed on lower metal line Mₓ can have similar attributes as etch stop layer 108 described above with respect to FIG. 3.

Referring to FIG. 7, in operation 704, ILD layer 106b is deposited, in accordance with some embodiments. ILD layer 106b can be formed similarly as ILD layer 106a described above with reference to FIG. 1.

Referring to FIG. 7, in operation 706, a dual damascene trench 800 can be formed in ILD layer 106b and liner 107 can be formed on inner surfaces of the dual damascene trench as shown in FIG. 8A, in accordance with some embodiments. Dual damascene trench 800 includes a vertical portion that will contain via Vₓ and a horizontal portion that will contain upper metal line Mₓ₊₁. The vertical portion of dual damascene trench 800 can extend downward, through etch stop layer 108 and graphene cap 110 and into the bulk metal of lower metal line Mₓ, to a recess depth R below a top surface of graphene cap 110, as shown in FIG. 8A.

Referring to FIG. 7, in operation 708, liner 107 is then formed on internal surfaces of dual damascene trench 800 as shown in FIG. 8A, in accordance with some embodiments. Formation of liner 107 excludes BFC 602 at the bottom of via Vₓ. Such a configuration can be fabricated by first conformally depositing liner 107 on internal surfaces of dual damascene trench 800, and then removing liner 107 from the bottom of via Vₓ using, for example, an anisotropic etching process. Alternatively, liner 107 can be selectively grown on ILD surfaces and not on exposed copper at BFC 602. Liner 107 can otherwise be applied to dual damascene trench 800 in a similar way as liner 107 is applied to lower metal line Mₓ in the above description of operation 702. Liner 107 can have a material composition that catalyzes subsequent formation of graphene on its surface, e.g., Co, Ta, or Ru.

Referring to FIG. 7, in operation 710, graphene cladding 112 is extended to the bottom and sidewalls of dual damascene trench 800 over liner 107 as shown in FIG. 8B, in accordance with some embodiments. Graphene cladding 112 as applied to dual damascene trench 800 is similar to graphene cladding 112 as applied to inner surfaces of lower metal line Mₓ in the above description of operation 702. Graphene cladding 112 can be selectively grown, first on liner 107, and then on exposed copper so that the bottom surface of Via Vₓ is lined with graphene cladding 112 as shown in FIG. 8B. Selectivity of graphene formation on the various surfaces can be tuned to achieve different thicknesses on the different surfaces. For example, 3 to 20 monolayers of graphene can be formed on surfaces bearing liner 107, while only a few layers (e.g., 1-3 monolayers) of graphene are formed at BFC 602. In some embodiments, at operation 710, graphene cladding 112 can be formed by selective deposition onto liner 107, e.g., onto Co, to produce a cladding having thickness T_{GS}. Where there is no liner 107 at the bottom of via Vₓ, graphene can be formed on Cu by CVD, PVD, or another suitable process, to produce graphene cladding 112 at BFC 602 having thickness T_{GV}. Alternatively, graphene can be selectively grown on exposed metal within metal line Mₓ at the bottom of via Vₓ to form graphene cladding 112 at BFC 602. In some embodiments, graphene cladding formed on Co has more layers and is thicker than graphene cladding formed on Cu (T_{GS}>T_{GV}). Different graphene thicknesses are produced at the different sites due to differences in the catalyzed surfaces.

Referring to FIG. 7, in operation 712, upper metal line Mₓ₊₁ can be formed as shown in FIG. 8C, in accordance with some embodiments. Vₓ and upper metal line Mₓ₊₁ can be filled simultaneously in a similar way as described above with respect to operation 410 and FIG. 5C. Depositing upper metal line Mₓ₊₁ may over-fill dual damascene trench 800 with copper, creating excess copper 804. Upper metal line Mₓ₊₁ can then be polished as shown in FIG. 8D, in accordance with some embodiments. Polishing can be accomplished using a CMP planarization process, as described above with respect to planarizing graphene-clad damascene interconnect structure 300 and contact layer 105. Following planarization, excess copper 804 has been removed, and a top surface of upper metal line Mₓ₊₁ is substantially co-planar with top surfaces of liner 107.

Referring to FIG. 7, in operation 714, a graphene cap 110 can be formed on the top surface of upper metal line Mₓ₊₁ as shown in FIG. 8D, in accordance with some embodiments. In some embodiments, graphene cap 110 can be selectively deposited onto the conductive metal surface of upper metal line Mₓ₊₁. Graphene cap 110 formed on upper metal line Mₓ₊₁ can be fabricated similarly and can have similar attributes as graphene cap 110 formed on lower metal line Mₓ as described above with respect to operation 702.

Referring to FIG. 7, in operation 716, etch stop layer 108 can be formed on upper metal line Mₓ₊₁ as shown in FIG. 8E, in accordance with some embodiments. Etch stop layer 108 formed on top of upper metal line Mₓ₊₁ can be fabricated similarly and can have similar attributes as etch stop layer 108 formed on top of lower metal line Mₓ as described above in operation 702. Formation of etch stop layer 108 completes graphene-clad damascene interconnect structure 600.

Operations 704-716 can then be repeated to form additional dual damascene interconnect structures on top of graphene-clad damascene interconnect structure 600, up to about metal line M5.

FIG. 9 shows a cross-sectional view of a graphene-clad damascene interconnect structure 900, e.g., a multi-layer type of graphene-clad metal interconnect structure that could be used as GC1 or GC2 shown in FIG. 1, in accordance with some embodiments. In some embodiments, graphene-clad damascene interconnect structure 900 can be similar to graphene-clad damascene interconnect structure 600, with some exceptions. Like graphene-clad damascene interconnect structure 600, graphene-clad damascene interconnect structure 900 features a barrier-free contact (BFC) 602 at the bottom of via Vₓ. That is, the bottom surface of via Vₓ includes graphene cladding 112 but does not include barrier/liner 107. Graphene-clad damascene interconnect structure 900 differs from graphene-clad interconnect structures 300 and 600 in that liner 107 is omitted. Consequently, because graphene cladding 112 is deposited directly onto ILD surfaces, graphene cladding 112 within graphene-clad damascene interconnect structure 900 may have a substantially uniform thickness T_{L}. Because liner 107 is not present, graphene-clad damascene interconnect structure 900 relies on graphene cladding 112 to provide a diffusion barrier.

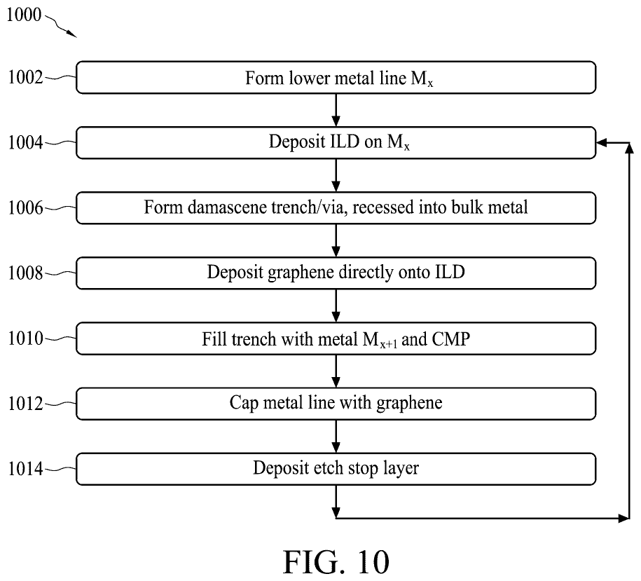

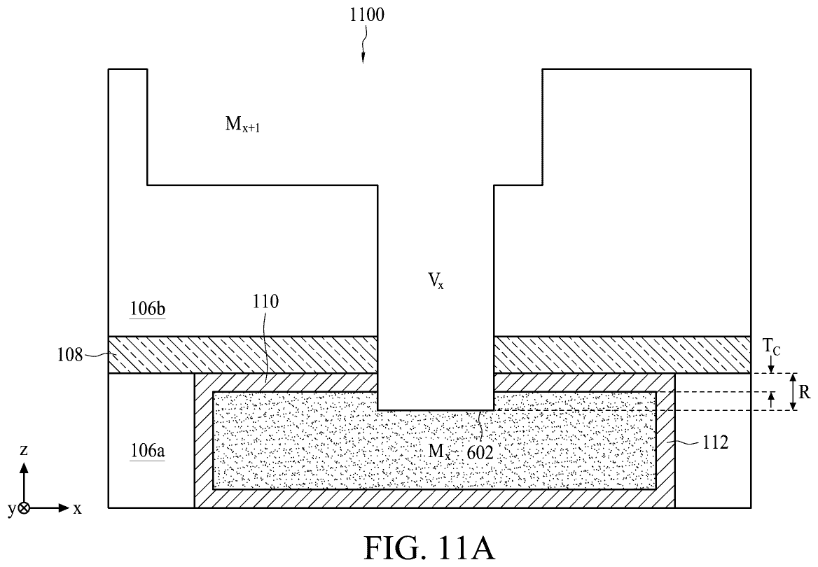

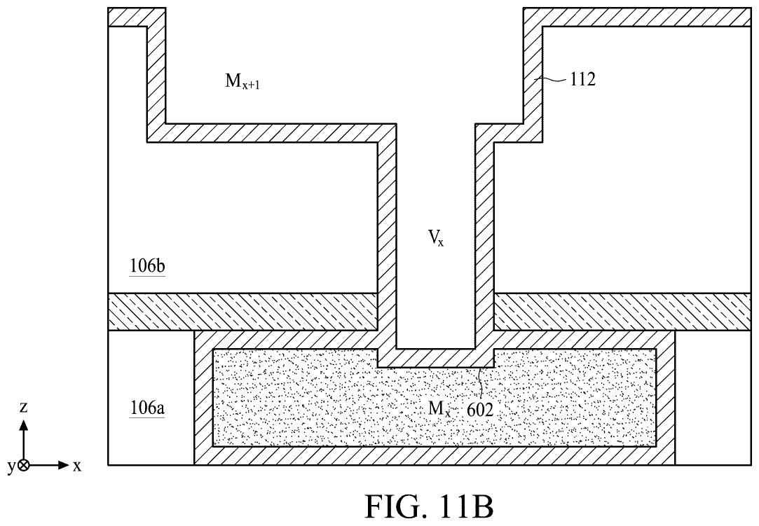

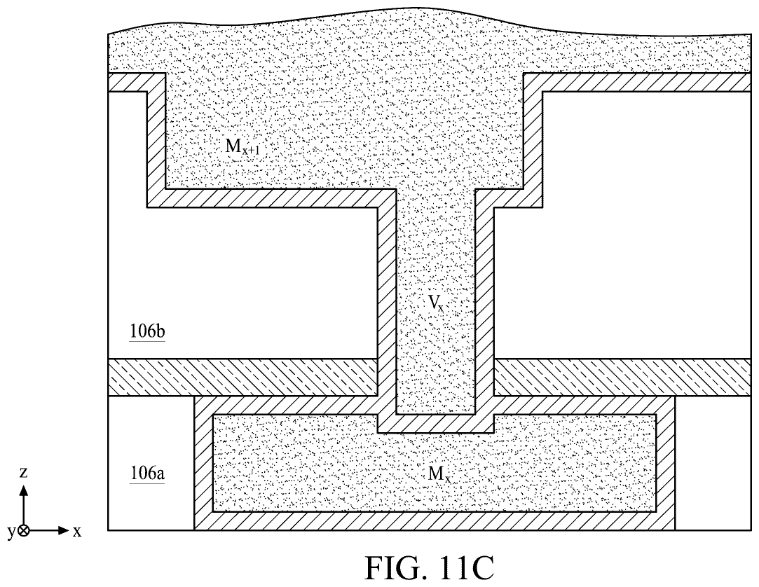

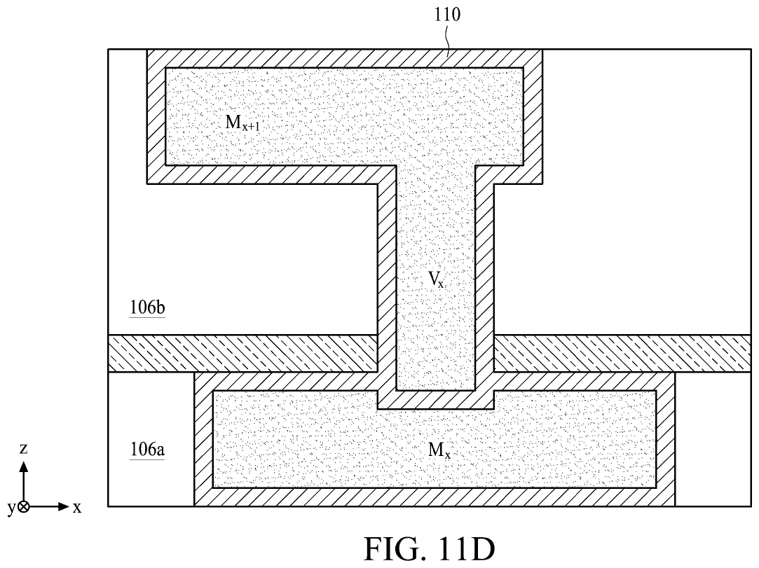

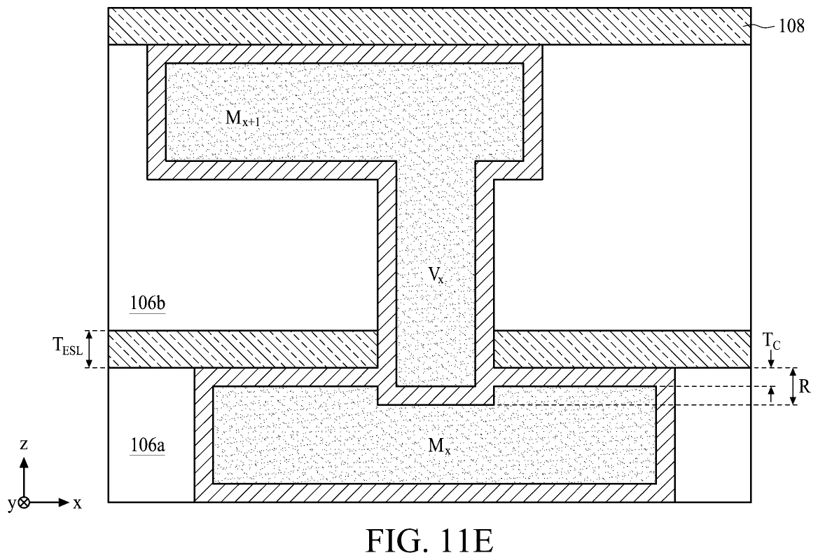

FIG. 10 illustrates a method 1000 for fabricating graphene-clad damascene interconnect structure 900, according to some embodiments. Operations illustrated in FIG. 10 will be described with reference to processes for fabricating graphene-clad damascene interconnect structure 900 as illustrated in FIGS. 11A-11E, a sequence of cross-sectional views of graphene-clad damascene interconnect structure 900 at various stages of its fabrication. Operations of method 1000 can be performed in a different order, or not performed, depending on specific applications. It is noted that method 1000 may not produce a complete graphene-clad damascene interconnect structure 900. Accordingly, it is understood that additional processes can be provided before, during, or after method 1000, and that some of these additional processes may be briefly described herein.

Method 1000 for fabricating graphene-clad damascene interconnect structure 900 is similar to method 700 for fabricating graphene-clad damascene interconnect structure 600 in many respects, with a few exceptions, in accordance with some embodiments. Because graphene-clad damascene interconnect structure 900 does not include liner 107, formation of graphene cladding 112 occurs directly on ILD surfaces of the single damascene trench for lower metal line Mₓ. Similarly, formation of graphene cladding 112 occurs directly on ILD surfaces of the dual damascene trench for via Vₓ and upper metal line Mₓ₊₁. In some embodiments, the ILD material can be SiO₂, SiOC, or another low-k material. In some embodiments, graphene cladding 112 is grown on ILD layer 106a or 106b using a thermal CVD process or a remote plasma-enhanced CVD (PECVD) process. Thicknesses of graphene cladding 112 throughout graphene-clad damascene interconnect structure 900 can therefore be substantially uniform.

Referring to FIG. 10, in operation 1002, lower metal line Mₓ is formed as shown in FIG. 11A, in accordance with some embodiments. Operation 1002 can proceed similarly as operation 702 described above. As a result, lower metal line Mₓ as shown in FIG. 9 may have similar characteristics as lower metal line Mₓ shown in FIG. 6, with the exception that liner 107 is omitted.

Referring still to FIG. 10, in operation 1002, a graphene cap 110 can be formed on lower metal line Mₓ as shown in FIG. 11A, in accordance with some embodiments. When the trench is full, graphene cap 110 can be deposited over the top surface of copper. In some embodiments, graphene cap 110 has a thickness T_{C} that can be as thick as T_{Mx+1}/10. Finally, etch stop layer 108 can be deposited on metal line Mₓ as shown in FIG. 11A, in accordance with some embodiments. In some embodiments, etch stop layer 108 can be formed with a compressive strain so as to improve adhesion of underlying graphene cap 110 to metal line Mₓ. A high compressive strain can be achieved by forming etch stop layer 108 from materials, such as SiN, SiCN, SiC, and AlN.

Referring to FIG. 10, in operation 1004, ILD layer 106b is deposited, in accordance with some embodiments.

Referring to FIG. 10, in operation 1006, a dual damascene trench 1100 can be formed in ILD layer 106b as shown in FIG. 11A, in accordance with some embodiments. Dual damascene trench 1100 includes a vertical portion that will contain via Vₓ and a horizontal portion that will contain upper metal line Mₓ₊₁. The vertical portion of dual damascene trench 1100 can extend downward, through etch stop layer 108 and graphene cap 110, into the bulk metal of lower metal line Mₓ, to a recess depth R, below a top surface of graphene cap 110, as shown in FIG. 11A.

Referring to FIG. 10, in operation 1008, graphene cladding 112 can be deposited onto inner surfaces of dual damascene trench 1100 as shown in FIG. 11B, in accordance with some embodiments. Graphene cladding 112 as applied to dual damascene trench 1100 is similar to graphene cladding 112 as applied to inner surfaces of lower metal line Mₓ in the above description of operation 1002. Graphene cladding 112 can be conformally deposited on ILD layer 106b, and then on exposed copper so that the bottom surface of Via Vₓ is lined with graphene cladding 112 as shown in FIG. 11B. Graphene can be formed by CVD, PVD, or another suitable process, to produce graphene cladding 112 having substantially uniform thickness.

Referring to FIG. 10, in operation 1010, upper metal line Mₓ₊₁ can be formed as shown in FIG. 11C, in accordance with some embodiments. Vₓ and upper metal line Mₓ₊₁ can be filled simultaneously in a similar way as described above with respect to operation 710 and FIG. 8C.

Referring to FIG. 10, in operation 1012, a graphene cap 110 can be formed on the top surface of upper metal line Mₓ₊₁ as shown in FIG. 11D, in accordance with some embodiments. In some embodiments, graphene cap 110 can be selectively deposited onto the conductive metal surface of upper metal line Mₓ₊₁. Graphene cap 110 formed on upper metal line Mₓ₊₁ can be fabricated similarly and can have similar attributes as graphene cap 110 formed on lower metal line Mₓ as described above in operation 1002.

Referring to FIG. 10, in operation 1014, etch stop layer 108 can be formed on upper metal line Mₓ₊₁ as shown in FIG. 11E, in accordance with some embodiments. Etch stop layer 108 formed on top of upper metal line Mₓ₊₁ can be fabricated similarly and can have similar attributes as etch stop layer 108 formed on top of lower metal line Mₓ as described above in operation 1002. Formation of etch stop layer 108 completes graphene-clad damascene interconnect structure 900. Operations 1006-1014 can then be repeated to form additional dual damascene interconnect structures on top of graphene-clad damascene interconnect structure 900, up to about metal line M5.

FIG. 12 shows a cross-sectional view of a graphene-clad patterned interconnect structure 1200, e.g., a multi-layer type of graphene-clad metal interconnect structure that could be used as GC1 or GC2 shown in FIG. 1, in accordance with some embodiments. Graphene-clad patterned interconnect structure 1200 can be formed without the use of a damascene process, by using metal lithography and metal etching processes. In some embodiments, graphene-clad patterned interconnect structure 1200 includes a conformal etch stop layer 1208 that wraps around three sides of the metal lines. In some embodiments, graphene-clad patterned interconnect structure 1200 includes various catalytic layers that can facilitate the growth of graphene cladding 112 around lower metal lines Mₓ and upper metal lines Mₓ₊₁. Such layers can include, for example, bottom catalytic layers 1214 and top/sidewall catalytic layers 1216. In some embodiments, the formation of graphene cladding 112 in graphene-clad patterned interconnect structure 1200 differs from other embodiments described above, e.g., graphene-clad damascene interconnect structures 300, 600, and 900, in that bottom layers of graphene cladding 1210 underneath lower and upper metal lines Mₓ and Mₓ₊₁ are formed separately from top and side portions of graphene cladding 112. Whereas, in other graphene-clad damascene interconnect structures 300, 600, and 900, the bottom and sides of graphene cladding 112 are formed together, and then the top portion is formed as a capping layer 110. Thus, in graphene-clad patterned interconnect structure 1200, the graphene cladding includes a bottom layer of graphene cladding 1210 instead of capping layer 110. In some embodiments, graphene-clad patterned interconnect structure 1200 includes a liner 107 around vias Vₓ. In some embodiments, graphene-clad patterned interconnect structure 1200 omits graphene cladding around vias Vₓ. In some embodiments, materials and thicknesses of various layers within graphene-clad patterned interconnect structure 1200 can differ from corresponding materials and thicknesses in damascene structures of graphene-clad interconnect structures 300, 600, and 900.

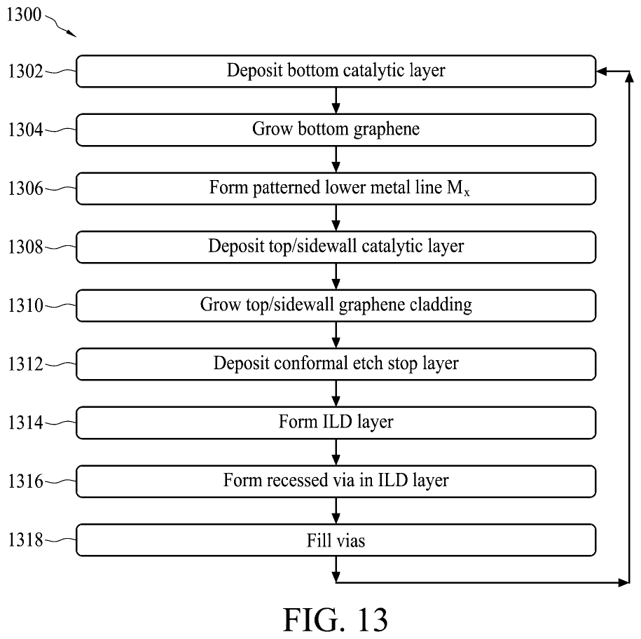

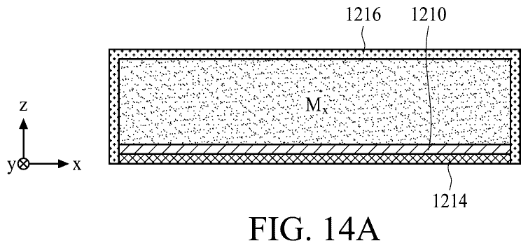

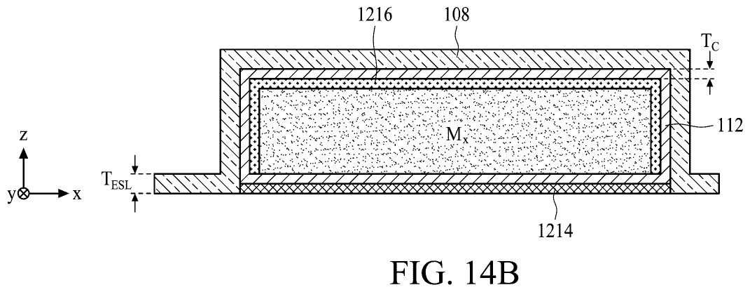

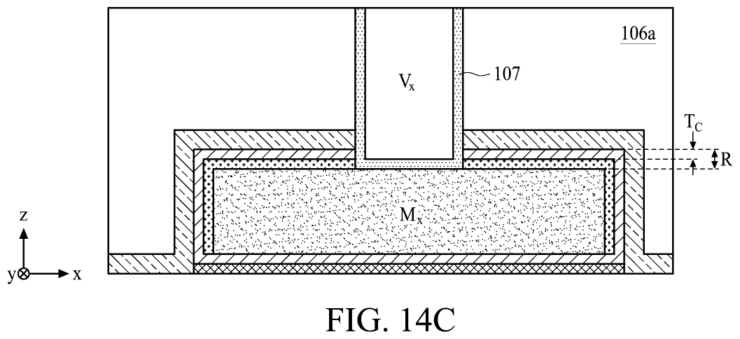

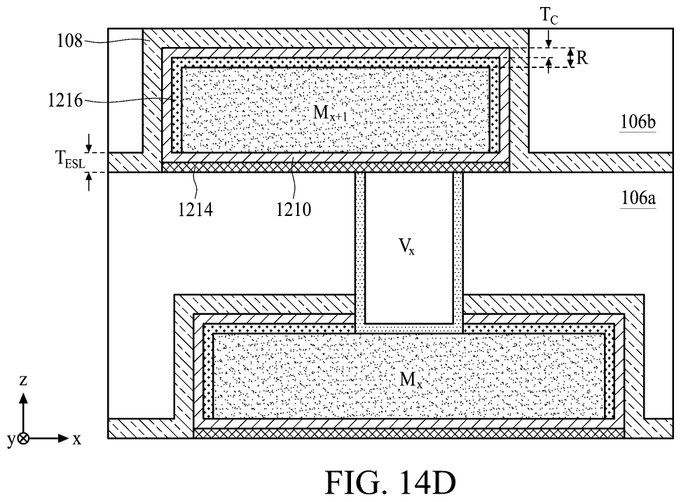

FIG. 13 illustrates a method 1300 for fabricating graphene-clad interconnect structure 1200, according to some embodiments. Operations illustrated in FIG. 13 will be described with reference to processes for fabricating graphene-clad patterned interconnect structure 1200 as illustrated in FIGS. 14A-14D, a sequence of cross-sectional views of graphene-clad patterned interconnect structure 1200 at various stages of its fabrication. Operations of method 1300 can be performed in a different order, or not performed, depending on specific applications. It is noted that method 1300 may not produce a complete graphene-clad interconnect structure 1200. Accordingly, it is understood that additional processes can be provided before, during, or after method 1300, and that some of these additional processes may be briefly described herein.

Method 1300 for fabricating graphene-clad patterned interconnect structure 1200 differs from methods 400, 700, and 1000 described above in that method 1300 forms metal lines Mₓ and Mₓ₊₁ by depositing and patterning metal as opposed to using a damascene trench-and-fill method. Vias Vₓ are formed separately by etching via openings in ILD and filling with a conductive metal. In addition, catalytic layers 1214 and 1216 are formed prior to graphene cladding 112 and graphene caps 110.

Referring to FIG. 13, in operation 1302, lower metal line Mₓ is formed as shown in FIG. 14A, in accordance with some embodiments. First, bottom catalytic layer 1214 is formed by deposition, patterning, and etching. Catalytic layer 1214 serves two purposes. First, a metallic catalytic layer 1214 facilitates selective growth of graphene. Second, catalytic layer 1214 serves as a diffusion barrier. Materials suitable for both purposes include, for example, Ta, Ru, and Ti. In some embodiments, bottom catalytic layer 1214 can have a thickness up to ½ T_{Mx}.

Referring to FIG. 13, in operation 1304, a bottom layer of graphene cladding 1210 can be grown on bottom catalytic layer 1214 as shown in FIG. 14A, in accordance with some embodiments. Graphene cladding 112 can be grown using a CVD process. In some embodiments, graphene cladding 112 is between 1 and 20 atomic layers thick.

Referring to FIG. 13, in operation 1306, lower metal line Mₓ is formed over the bottom layer of graphene cladding 1210, as shown in FIG. 14A, in accordance with some embodiments. Lower metal line Mₓ can be deposited and patterned using a lithography/etching process. Metals suitable for patterning lower metal line Mₓ include Cu, Co, W, Al, Ta, and Ru, for example.

Referring to FIG. 13, in operation 1308, top/sidewall catalytic layer 1216 is formed as shown in FIG. 14A, in accordance with some embodiments. Top/sidewall catalytic layer 1216 can be formed by electroless plating or by CVD selective deposition on the remaining top and sides of lower metal line Mₓ. In some embodiments, top/sidewall catalytic layer 1216 can be made of a similar material as bottom catalytic layer 1214, such as Ta, Ru, and Ti. In some embodiments, top/sidewall catalytic layer 1216 can be made of a different material than bottom catalytic layer 1214, such as Cu, Ni, and Co. In some embodiments, top/sidewall catalytic layer 1216 has a thickness up to ⅕ T_{Mx}. Top/sidewall catalytic layer 1216, like bottom catalytic layer 1214, facilitates growth of graphene.

Referring to FIG. 13, in operation 1310, top and sidewall portions of graphene cladding 112 can be grown on top/sidewall catalytic layer 1216, as shown in FIG. 14B, in accordance with some embodiments. In some embodiments, the top portion of graphene cladding 112 has a thickness T_{C} that can be as thick as T_{Mx+1}/10.

Referring still to FIG. 13, in operation 1312 etch stop layer 108 can be deposited conformally onto lower metal line Mₓ as shown in FIG. 14B in accordance with some embodiments. In some embodiments, etch stop layer 108 includes one or more of SiCN, SiC, SiN, AlN, AlO₂, SiO₂, or other materials that tend to be more etch-resistant than low-k ILD materials, such as SiOC. In some embodiments, etch stop layer 108 can be a single blocking layer having a thickness in a range from about 100 Å to about 150 Å. In some embodiments, etch stop layer 108 can be a multi-layer stack that includes, for example, a blocking layer and a TEOS capping layer. In some embodiments, etch stop layer 108 has a thickness, T_{ESL}, based on a thickness of lower metal line Mₓ. For example, T_{ESL} for patterned metal lines can be in a range from about T_{Mx}/10 to about T_{Mx}/2. It is noted that definitions of thicknesses T_{C}, T_{L}, T_{ESL}, and T_{Mx+1} are indicated in the magnified cross-sectional view shown in FIG. 3. In some embodiments, etch stop layer 108 can be formed with a high density and/or a compressive strain so as to improve adhesion of underlying graphene cladding 112 to metal line Mₓ. A high compressive strain can be achieved by forming etch stop layer 108 from materials, such as SiN, SiCN, SiC, and AlN, using CVD or PVD.

Referring to FIG. 13, in operation 1314, ILD layer 106b is deposited, in accordance with some embodiments. In some embodiments, ILD layer 106b can be deposited using a CVD process to cover lower metal line Mₓ as well as an additional thickness of ILD in which via Vₓ can be formed in operation 1316. ILD layer 106b can then be polished using a CMP process.

Referring to FIG. 13, in operation 1316, a recessed via can be formed in planarized ILD layer 106b as illustrated in FIG. 14C, in accordance with some embodiments. First, a via opening can etched into ILD layer 106b, extending downward, through etch stop layer 108, the top portion of graphene cladding 112, and top/sidewall catalytic layer 1216. The via opening extends into the bulk metal of lower metal line Mₓ, to a recess depth R, below a top surface of graphene cladding 112, as shown in FIG. 14A. In some embodiments, R is in a range of about 0.5 to about 5 times the thickness of the top portion of graphene cladding 112. The etching process can be fluorine-based, for accelerated removal of ILD layer 106b.

Referring to FIG. 13, in operation 1318, vias Vₓ can be filled with metal as shown in FIG. 14C, in accordance with some embodiments. First, liner 107 can be deposited onto inner surfaces of the via opening. Liner 107 can be conformally deposited on sidewalls of the via opening, that is, onto ILD layer 106b, and then on exposed copper at the bottom surface of Via Vₓ. In some embodiments, Liner 107 within via Vₓ can have a thickness up to about (VₓBCD)/4, wherein VXBCD is in a range of about 0.5 to about 2 times the minimum metal width, w, of lower metal line Mₓ. After liner 107 is in place, via Vₓ can be filled with a conductive metal, for example, W, Cu, Ta, Ru, or Co.

Referring to FIG. 13, operations 1302-1310 can be repeated as shown in FIG. 14D to form patterned upper metal line Mₓ₊₁, in accordance with some embodiments. Repeating operations 1302-1310 forms a graphene-clad upper metal line Mₓ₊₁ in a similar fashion to the way in which lower metal line Mₓ was formed. In some embodiments, details of the formation and structure of upper metal line Mₓ₊₁ shown in FIG. 14D are consistent with the description above of corresponding aspects of lower metal line Mₓ. By repeating operation 1302, bottom catalytic layer 1214 is deposited, followed by bottom layer of graphene cladding 1210 in operation 1304, and patterned upper metal line Mₓ₊₁, in operation 1306. Patterned conductive metal materials suitable for upper metal line Mₓ₊₁ can include one or more of Cu, Co, W, Al, Ta, or Ru. Subsequently, top/sidewall catalytic layer 1216 is formed on upper metal line Mₓ₊₁, followed by top and sidewall portions of graphene cladding 112, as shown in FIG. 14D.

Referring to FIG. 13, in operation 1312, a conformal etch stop layer 108 is formed over graphene-clad upper metal line Mₓ₊₁, as shown in FIG. 14D. Etch stop layer 108 formed on upper metal line Mₓ₊₁ can be fabricated similarly and can have similar attributes as etch stop layer 108 formed on lower metal line Mₓ with respect to operation 1312 as described above. In some embodiments, etch stop layer 108 can have a thickness T_{ESL} in a range of about 1/10 T_{Mx}. to about ½ T_{Mx}. Formation of etch stop layer 108 completes graphene-clad patterned interconnect structure 1200. Operations 1314-1318 can then be repeated to form an additional via Vₓ (not shown) above upper metal line Mₓ₊₁. Operations 1302-1318 can then be repeated to stack additional graphene-clad patterned interconnect structures 1200 on top of Mₓ+L.

FIG. 15 shows a cross-sectional view of a graphene-clad interconnect structure 1500, e.g., a graphene-clad metal interconnect structure that could be used as GC1 or GC2 shown in FIG. 1, in accordance with some embodiments. Graphene-clad interconnect structure 1500 is a variation of graphene-clad patterned interconnect structure 1200 in which the via, CNT-Vₓ, is filled with carbon nanotubes (CNTs) instead of metal. The CNTs can be grown simultaneously with top/sidewall portions of graphene cladding 112 on lower metal layer Mₓ. CNT growth can be guided by a via template 1504 formed from a metal oxide. In graphene-clad interconnect structure 1500, etch stop layer 108 covers sidewalls of via CNT-Vₓ.

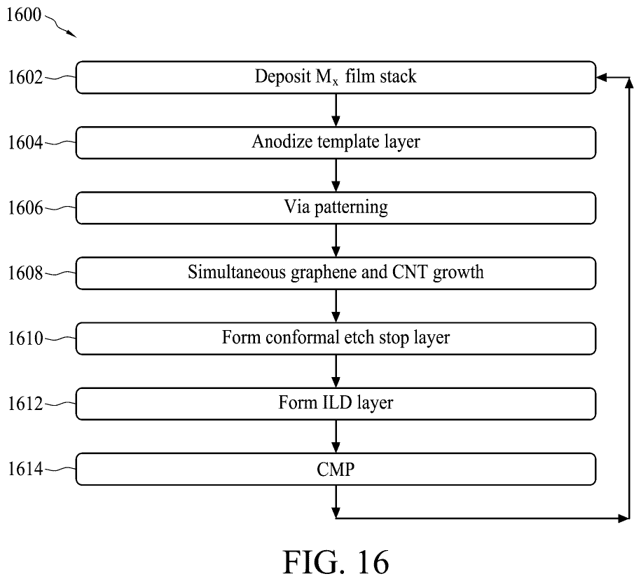

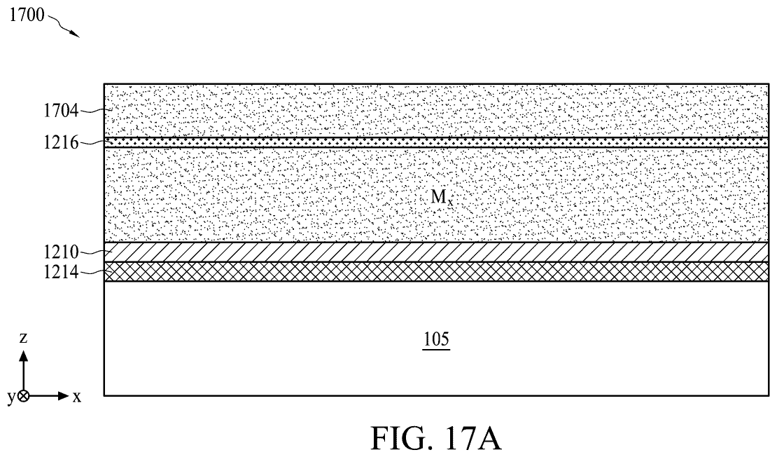

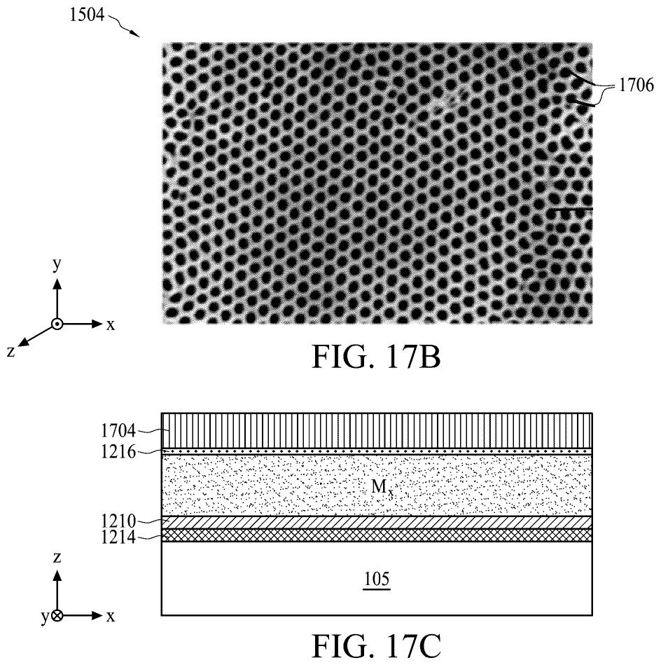

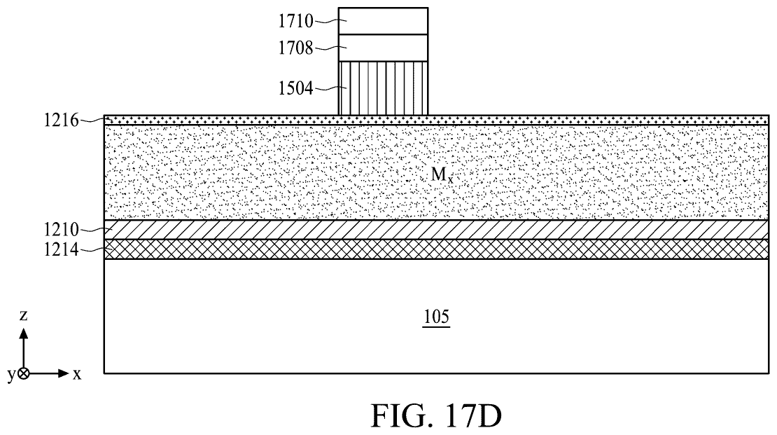

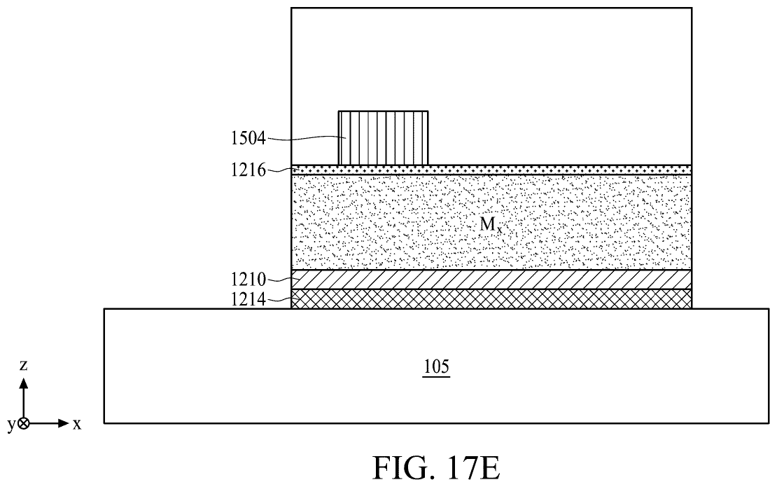

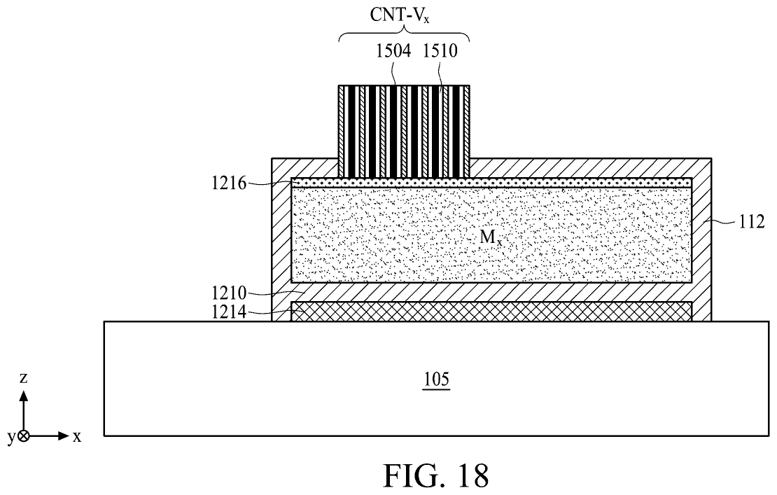

FIG. 16 illustrates a method 1600 for fabricating graphene-clad patterned interconnect structure 1500, according to some embodiments. Operations illustrated in FIG. 16 will be described with reference to processes for fabricating graphene-clad patterned interconnect structure 1500 as illustrated in FIGS. 17A-17E, 18, and 19A-19C, a sequence of cross-sectional views of graphene-clad patterned interconnect structure 1500 at various stages of its fabrication. Operations of method 1600 can be performed in a different order, or not performed, depending on specific applications. It is noted that method 1600 may not produce a complete graphene-clad interconnect structure 1500. Accordingly, it is understood that additional processes can be provided before, during, or after method 1600, and that some of these additional processes may be briefly described herein.

Referring to FIG. 16, in operation 1602, metal film stack 1700 can be formed as illustrated in FIG. 17A, according to some embodiments. Metal film stack 1700 can include bottom catalytic layer 1214, bottom layer of graphene cladding 1210, blanket metal deposition for lower metal line Mₓ, top catalytic layer 1216, and a template layer 1704. The various layers of metal film stack 1700 underneath template layer 1704 can have similar attributes as corresponding layers of graphene-clad patterned interconnect structure 1200, as described above with respect to method 1300. Materials suitable for template layer 1704 include, for example, Al, AlO₂, Si, Ta, and magnesium (Mg), which can be deposited using a PECVD process.

Referring to FIG. 16, in operation 1604, template layer 1704 can be anodized as shown in FIGS. 17B and 17C, according to some embodiments. In some embodiments, the anodization process oxidizes template layer 1704 and creates a 2-D array of micropores 1706 that extend through template layer 1704 to expose portions of top catalytic layer 1216. The effect of micropores 1706 produces a regular pattern of narrowly spaced openings in template layer 1704, as shown in FIG. 17C, without the use of lithography or etching operations. In some embodiments, openings in template layer 1704 have spacings in the range of about 50 nm to about 500 nm. This regular pattern of openings serves as via template 1504, providing a vertical support structure to guide subsequent formation of CNTs in a columnar array. In some embodiments, micropores 1706, e.g., micropores formed by anodizing aluminum oxide, or alumina, are arranged in a hexagonal pattern as shown in FIG. 17B. The hexagonal pattern can be formed by self-organization of atoms in template layer 1704.

Referring to FIG. 16, in operation 1606, template layer 1704 having micropores 1706 can be patterned using a lithography/etch process to form via template 1504 as shown in FIGS. 17D and 17E, according to some embodiments. First, an organic anti-reflective coating, or organic ARC 1708 can be blanket deposited over via template 1504 for use as a hard mask. Then, photoresist 1710 can be used to pattern ARC 1708. Then ARC 1708 can be used as a mask to etch via template 1504, stopping on top catalytic layer 1216, as shown in FIG. 15. A CF₄/O₂ plasma etch can be used to achieve a desired VxBCD. In some embodiments, suitable choices for organic ARC 1708 have material properties that prevent ARC 1708 from entering micropores 1706. Following removal of ARC 1708 and photoresist 1710, the completed via template 1504 is shown in FIG. 17E.

Referring to FIG. 16, in operation 1608, via template 1504 is used to form graphene cladding 112 and CNTs 1510 as shown in FIG. 18, according to some embodiments. In some embodiments, CNTs and graphene cladding 112 can be grown simultaneously. Top catalytic layer 1216 facilitates growth of a columnar array of CNTs in micropores 1706, guided by via template 1504. The small dimensions of micropores 1706 mimic a rough surface, which results in formation of carbon nanotubes as opposed to carbon in the form of graphene. Meanwhile, graphene grows simultaneously on the smooth exposed top, and on smooth sidewalls, of metal film stack 1700 to form graphene cladding 112 in operation 1608. In some embodiments, graphene cladding 112 can be formed and can have attributes of, graphene cladding 112 as described above with respect to one or more of interconnect structures 300, 600, 900, or 1200.

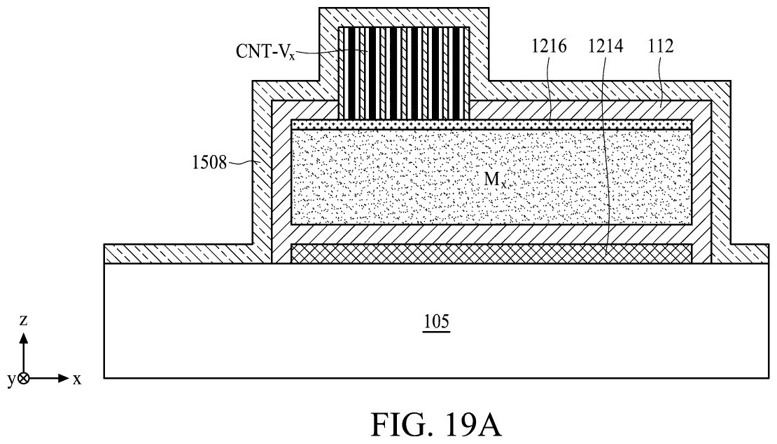

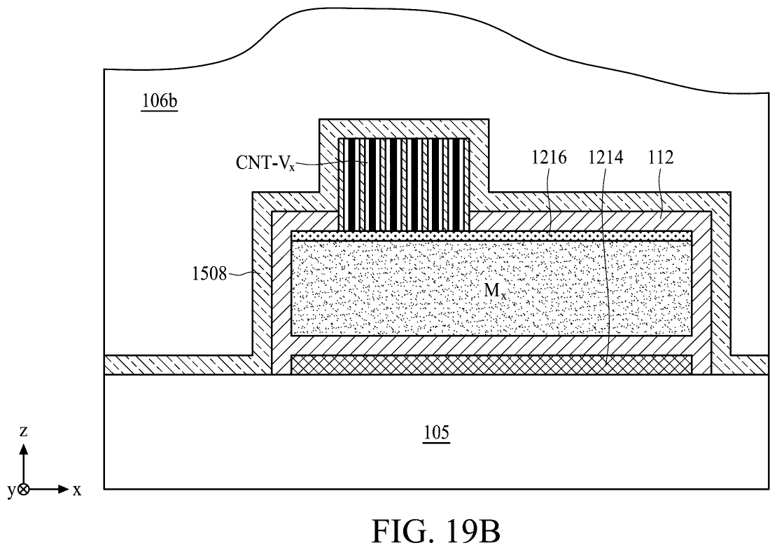

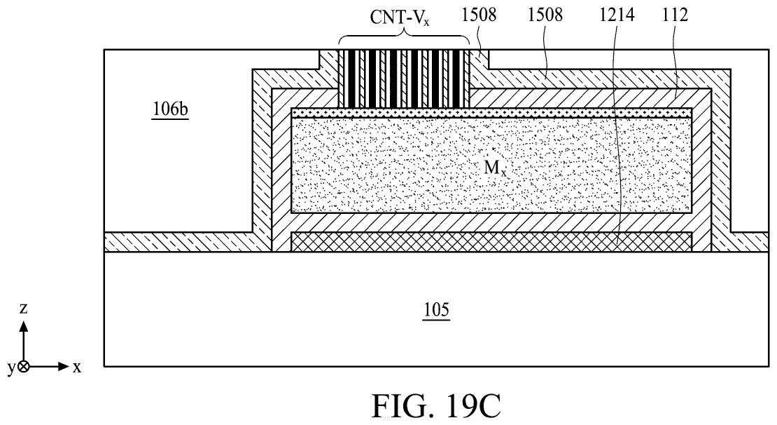

Referring to FIG. 16, in operation 1610, an etch stop layer 1508 can be conformally deposited over graphene-clad lower metal line Mₓ and CNT-Vₓ, as shown in FIG. 19A, according to some embodiments. Etch stop layer can be fabricated similarly and can have similar attributes as etch stop layer 108 shown in FIG. 12 and formed in operation 1312 as described above. In some embodiments, etch stop layer 1508 can have a thickness T_{ESL} in a range of about 1/10 T_{Mx}. to about ½ T_{Mx}. In some embodiments, etch stop layer 1508 can be a high-density dielectric film that enhances adhesive strength of graphene cladding 112 to lower metal line Mₓ and CNT-Vₓ, e.g., SiN, SiCN, or AlN.

Referring to FIG. 16, in operation 1612, ILD layer 106b is deposited over etch stop layer 1508 as shown in FIG. 19B, according to some embodiments. In some embodiments, ILD layer 106b can be fabricated similarly and can have similar attributes as ILD layer 106b shown in any of interconnect structures 300, 600, 900, or 1200, as described above. In some embodiments, suitable materials for use as ILD layer 106b, in the context of graphene-clad patterned interconnect structure 1500, include porous, low-k dielectrics. In some embodiments, materials suitable for use as ILD layer 106b, in the context of graphene-clad patterned interconnect structure 1500 have a density less than the density of etch stop layer 1508, e.g., SiOC, SiO₂, or air.

Referring to FIG. 16, in operation 1614, ILD layer 106b can be planarized in a CMP operation, as shown in FIG. 19C, according to some embodiments. ILD layer 106b can be removed down to, and including, the uppermost portion of etch stop layer 1508, so that ILD layer 106b is co-planar with the top of CNT-Vₓ. Operations 1602-1614 can then be repeated to form additional vias and metal lines above Mₓ₊₁, up to about metal line M₅.

The examples described above and shown in FIGS. 3, 6, 9, 12, and 15 illustrate various configurations of graphene-clad metal lines that can leverage the unique properties of graphene to benefit interconnect performance for semiconductor devices. Embodiments of FIGS. 3, 6, and 9 can be fabricated using a damascene process flow, whereas the embodiments of FIGS. 12 and 15 can be fabricated by patterning metal lines. Some embodiments include a barrier/liner layer outside the graphene cladding; others include a catalytic layer inside the graphene cladding. The example of FIG. 15 incorporates graphene in two different forms—a graphene-clad metal line and a carbon nanotube-filled via. Variations of such methods and structures are within the scope of the present disclosure.

In some embodiments, a method includes: forming a transistor structure on a semiconductor substrate; forming a contact layer for contacts to source, drain, and gate terminals of the transistor structure; and forming a graphene-clad metal interconnect. In some embodiments, forming the graphene metal interconnect includes: depositing a first inter-layer dielectric (ILD) layer over the contact layer; and forming, in the first ILD layer, a metal layer. In some embodiments, forming the graphene metal interconnect further includes: forming a first graphene cladding on sidewalls and a lower surface of the metal layer; and a first graphene cap; depositing a second ILD layer over the metal layer; and etching an opening in the second ILD layer. In some embodiments, forming the metal layer further includes filling the opening with: a second graphene cladding on sidewall and horizontal surfaces of the opening; a metal fill on the second graphene cladding; and a second graphene cap over the metal fill.

In some embodiments, a method includes: forming a transistor layer on a semiconductor substrate; coupling a contact layer to the transistor layer; and coupling a patterned metal interconnect to the contact layer, where the patterned metal interconnect includes: first and second graphene-clad metal lines; and a via coupling the first and second graphene-clad metal lines to each other.

In some embodiments, a structure includes: a transistor structure; an interconnect structure coupled to the transistor structure, the interconnect structure including a graphene-clad metal line; an inter-layer dielectric (ILD) layer on the graphene-clad metal line; and a graphene-clad via, in the ILD layer, coupled to the graphene-clad metal line.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a transistor structure on a semiconductor substrate;
forming a contact layer for contacts to source, drain, and gate terminals of the transistor structure; and
forming a graphene-clad metal interconnect, comprising:
depositing a first inter-layer dielectric (ILD) layer over the contact layer;
forming, in the first ILD layer, a metal layer that comprises:
a first graphene cladding on sidewalls and a lower surface of the metal layer; and
a first graphene cap;
depositing a second ILD layer over the metal layer;
etching an opening in the second ILD layer; and
filling the opening with:
a second graphene cladding on sidewall and horizontal surfaces of the opening;
a metal fill on the second graphene cladding; and
a second graphene cap over the metal fill.

2. The method of claim 1, wherein forming the graphene-clad metal interconnect further comprises forming a liner adjacent to the graphene cladding.

3. The method of claim 2, wherein the liner surrounds the first and second graphene claddings.

4. The method of claim 2, wherein the liner surrounds the first graphene cladding and the second graphene cladding on selected surfaces of the dual damascene opening.

5. The method of claim 2, wherein forming the liner comprises forming a layer of cobalt, tantalum, ruthenium, and combinations thereof.

6. The method of claim 2, wherein forming the graphene-clad metal interconnect comprises selectively forming graphene on the liner.

7. The method of claim 6, wherein selectively forming the graphene comprises depositing carbon atomic layers in one or more of a chemical vapor deposition (CVD) process, a plasma vapor deposition (PVD) process, a plasma-enhanced chemical vapor deposition (PECVD) process, and an atomic layer deposition (ALD) process.

8. The method of claim 1, wherein forming the first and second graphene claddings and the first and second graphene caps comprise surrounding the metal fill with a multi-layer graphene film.

9. The method of claim 1, wherein the metal fill comprises one or more of copper, cobalt, tungsten, ruthenium, and tantalum.

10. The method of claim 1, wherein forming the graphene-clad metal interconnect further comprises forming an etch stop layer on the first and second graphene caps.

11. A method, comprising:
forming a transistor on a semiconductor substrate;
coupling a contact layer to the transistor; and
coupling a patterned metal interconnect to the contact layer, wherein the patterned metal interconnect comprises:
first and second graphene-clad metal lines; and
a via coupling the first and second graphene-clad metal lines to each other.

12. The method of claim 11, further comprising depositing an etch stop layer on the first and second graphene-clad metal lines.

13. The method of claim 11, wherein coupling the patterned metal interconnect to the contact layer comprises:
depositing a graphene layer on the contact layer;
depositing a first metal layer on the graphene layer;
removing selected portions of the first metal layer to form a patterned metal line;
conformally depositing graphene on top and sidewall surfaces of the patterned metal line to form the first graphene-clad metal line;
conformally depositing an etch stop layer over the graphene;
depositing an inter-layer dielectric (ILD) over the etch stop layer;
forming a via in the ILD; and
repeating the depositing, removing, and conformally depositing, to form the second graphene-clad metal line on the ILD.

14. The method of claim 13, wherein removing the selected portions of the first metal layer comprises etching the first metal layer.

15. The method of claim 13, further comprising forming carbon nanotubes in the via.

16. The method of claim 15, wherein forming the carbon nanotubes comprises simultaneously growing carbon nanotubes and graphene.

17. A structure, comprising:
a transistor structure;
an interconnect structure coupled to the transistor structure, the interconnect structure comprising
a graphene-clad metal line;
an inter-layer dielectric (ILD) layer on the graphene-clad metal line; and
a graphene-clad via, in the ILD layer, coupled to the graphene-clad metal line.

18. The structure of claim 17, further comprising an etch stop layer formed above the graphene-clad metal line.

19. The structure of claim 17, wherein the interconnect structure further comprises a barrier film.

20. The structure of claim 19, wherein the via is in contact with the graphene-clad metal line.
